(19) United States
(12) Patent Application Publication
(10) Pub. No.: US 2016/0293346 A1
(43) Pub. Date: Oct. 6, 2016

(54) PSEUDOCAPACITIVE ELECTRODES AND METHODS OF FORMING

(71) Applicant: Purdue Research Foundation, West Lafayette, IN (US)

(72) Inventors: Guoping Xiong, West Lafayette, IN (US); Timothy Scott Fisher, West Lafayette, IN (US)

(21) Appl. No.: 14/871,010

(22) Filed: Sep. 30, 2015

Related U.S. Application Data
(60) Provisional application No. 62/143,113, filed on Apr. 5, 2015.

(51) Int. Cl. H01G 11/24; C30B 7/12; H01G 11/86; C30B 29/10; C30B 29/22; H01G 11/46; C30B 7/10; C30B 30/02

(52) U.S. Cl. CPC H01G 11/24; C30B 7/10; C30B 7/12; C30B 30/02; C30B 29/10; C30B 29/22; H01G 11/46; H01G 11/86

(57) ABSTRACT

Pesudocapacitive electrodes having improved electrochemical properties for energy storage systems, and methods for their manufacture. The pseudocapacitive electrode may include a porous substrate and a nanoscale structure having an array of nanoneedles or an array of nanopetals located on the substrate. The nanoscale structure includes a bi- or tri-metal oxide or a bi- or tri-metal hydroxide.

### CROSS REFERENCE TO RELATED APPLICATIONS

This application claims the benefit of U.S. Provisional Application No. 62/143,113, filed Apr. 5, 2015, the contents of which are incorporated herein by reference.

### STATEMENT REGARDING FEDERALLY SPONSORED RESEARCH

This invention was made with government support under Contract No. FA9550-12-1-0037 awarded by the United States Air Force. The Government has certain rights in the invention.

### BACKGROUND OF THE INVENTION

The present invention generally relates to energy storage systems. More particularly, this invention relates to improved pseudocapacitive electrode materials for energy storage systems, including but not limited to supercapacitors.

The increasingly growing demand for power supplies in practical applications such as electric vehicles and hybrid electric vehicles has attracted much interest in developing advanced energy storage devices. Among these energy storage systems, supercapacitors have sparked extensive attention because of their higher power density than batteries, higher energy density than conventional electrolytic capacitors, and other advantages such as long cycle life.

Designing new electrode materials with large surface areas and high electrical conductivities is crucial to enhancing the energy and power densities of supercapacitors. Pseudocapacitive electrode materials, particularly metal oxides/hydroxides containing transition metal elements (e.g., Ni, Co, Mn) that are endowed with rich redox states, can significantly improve energy densities compared to their carbon-based counterparts. However, their rate capabilities and long-term cycle life are typically poor because of their relatively low electrical conductivities. Consequently, high specific capacitances and energy densities can only be achieved at relatively low current densities (low charge/discharge rates), defeating the primary purpose of using a supercapacitor for high-rate charge/discharge applications. To alleviate this problem, binary metal oxides/hydroxides such as spinel nickel cobaltite (NiCo₂O₄) and related hydroxides have attracted particular interest recently because of their low-cost, abundant resources and environmental benignity. More significantly, their superior electrical conductivity (at least two orders of magnitude higher) and higher electrochemical activity (more active redox states) as compared to single-component metal oxides (e.g., nickel oxides and cobalt oxides) render them attractive electrode materials with high performance.

To further ameliorate the charge transfer efficiency and reduce internal resistance, much research has been dedicated to developing various substrates for supporting metal hydroxides suitable for use as pseudocapacitive electrode materials. Apart from commonly used substrates with relatively low surface areas (e.g., Ni foam and stainless steel), many carbon-based nanomaterials such as reduced graphene oxide and carbon nanotubes are frequently adopted as nanosubstrates for supporting metal hydroxide pseudocapacitive materials. However, fabricating such electrodes involves the use of binders and substrates/current collectors with a limited surface area; consequently, electrical conductivity, rate capability, energy density and long-term cycle life of electrodes are undermined as well as functional characteristics (e.g., flexibility, thermal limits) of the electrodes. Therefore, developing new substrates with high conductivity and high surface area to fully exploit the excellent pesudocapacitive properties of metal hydroxides and oxides remains an open challenge.

However, current metal hydroxide/oxide electrodes generally have several shortcomings, such as (I) complicated fabrication procedures (multi-step fabrication process), (ii) interfaces between the heterogeneous metal oxides that may reduce the electron transfer efficiency, and (iii) structures that are unlikely to fully utilize the electroactive sites of the mixed metal oxides/hydroxides.

Therefore, there is an ongoing desire for improved pesudocapacitive electrode materials and structures.

### BRIEF DESCRIPTION OF THE INVENTION

The present invention provides pesudocapacitive electrodes and methods of manufacture thereof having improved electrochemical properties for energy storage systems.

According to an aspect of the invention, a pseudocapacitive electrode is provided that includes a tri-metal oxide or tri-metal hydroxide.

According to another aspect of the invention, a pseudocapacitive electrode includes a porous substrate and a nanoscale structure having an array of nanoneedles or an array of nanopetals located on the substrate. The nanoscale structure includes a bi- or tri-metal oxide or bi- or tri-metal hydroxide.

According to yet another aspect of the invention, a method of forming a pseudocapacitive electrode includes forming on a porous substrate a nanoscale structure having an array of nanoneedles or an array of nanopetals. The nanoscale structure includes a bi- or tri-metal oxide or bi- or tri-metal hydroxide.

A technical effect of the invention is the ability to improve electrochemical performance of pseudocapacitive electrodes. In particular, it is believed that, a pseudocapacitive electrode comprising nanoneedles or nanopetals formed of a bi- or tri-metal oxide or bi- or tri-metal hydroxide can exhibit significantly increased performance over state-of-the-art single- and double-component metal hydroxides and oxides.

Other aspects and advantages of this invention will be better appreciated from the following detailed description.

### BRIEF DESCRIPTION OF THE DRAWINGS

FIGS. 1A through 1D are SEM images of: (A) Ni—Co—Mn hydroxide nanoneedles grown on Ni foam at low magnification (the inset shows the nanoneedles on Ni foam at a large scale); (B) precursor hydroxide nanoneedles at higher magnification; (C) Ni—Co—Mn oxide nanoneedles on Ni foam after annealing; and (D) Ni—Co—Mn oxide nanoneedles with ultra-sharp tips at high resolution.

FIGS. 2A through 2G are: (A) a TEM image of Ni—Co—Mn oxide nanoneedles; (B) a high-resolution TEM image revealing the porous structure of the Ni—Co—Mn oxide nanoneedles shown in FIG. 2A; (C) a high-angle annular dark field (HAADF) scanning TEM image of nanoneedles; and (D-G) elemental mapping showing uniform spatial distribution of mapped elements in the nanoneedles including Co, Ni, Mn, and O maps, respectively.

FIGS. 3A through 3D are: (A) an XRD pattern of Ni—Co—Mn oxide nanoneedles grown on Ni Foam; and (B-D) high-resolution XPS patterns of Ni 2p, Co 2p, and Mn 2p, respectively.

FIGS. 4A through 4D contain: (A) CV curves of Ni—Co—Mn oxide nanoneedle electrodes in 2 M KOH electrolyte from 5 to 100 m Vs⁻¹; (B) galvanostatic charge/discharge curves of Ni—Co—Mn oxide electrodes at different current densities in the voltage range between 0 and 0.4 V vs. SCE; (C) a plot showing specific capacitance as a function of discharge current density; and (D) a Ragone plot of Ni—Co—Mn oxide nanoneedle electrodes.

FIGS. 5A through 5C include: (A) a Nyquist plot for Ni—Co—Mn oxide nanoneedle electrodes recorded from 0.1 Hz to 1 MHZ; (B) capacitance retention and coulombic efficiencies during a charge/discharge cycling stability test of the Ni—Co—Mn oxide nanoneedle electrodes at a current density of 10 mA cm⁻²; and (C) a radar plot summarizing the electrochemical performance of the Ni—Co—Mn oxide nanoneedle electrodes.

FIG. 6 is a schematic representation of a hierarchical structure comprising Ni—Co hydroxide nanopetals on a free-standing graphene petal foam.

FIGS. 7A through 7F are images of: (FIG. 7A) free-standing graphene petal foam after etching Ni foam (the inset shows an optical image of graphene petal foam); (FIG. 7B) hollow channels after etching Ni ligaments (the inset image shows the thickness of the channel walls); (FIG. 7C) graphene petal foam uniformly covered by Ni—Co hydroxide nanopetals at a large scale; (FIG. 7D) smaller vertical Ni—Co hydroxide nanopetals densely grown on relatively larger graphitic petals; and (FIGS. 7E-7F) close-ups of a graphitic petal decorated by a large amount of smaller Ni—Co hydroxide nanopetals.

FIGS. 8A through 8H include: (FIG. 8A) a TEM image of a graphitic petal covered with a large amount of Ni—Co hydroxide nanopetals; (FIG. 8B) a high-resolution TEM image of a graphitic petal decorated by Ni—Co hydroxide nanopetals (the inset shows the FFT pattern of the red rectangular area); (FIG. 8C) a high-angle annular dark field (HAADF) scanning TEM image of a magnified part of a graphitic petal covered with many small Ni—Co hydroxide nanopetals; (FIGS. 8D-8G) elemental mapping showing a uniform spatial distribution of mapped elements in (FIG. 8C): (FIG. 8D) to (FIG. 8G) correspond to C, Ni, Co and O maps, respectively; and (FIG. 8H) an XRD pattern of graphene petal foam/Ni—Co hydroxide nanopetals.

FIGS. 9A through 9F are plots representing the electrochemical characterization of graphene petal foam/Ni—Co hydroxide nanopetal electrodes in 2 M KOH aqueous solution.

FIG. 10 is a schematic representation of a hierarchical structure of Ni—Co—Mn triple hydroxide nanoneedles on carbon cloth/graphitic petal substrates.

FIGS. 11A through 11J include: (FIG. 11A) an SEM image of a carbon cloth/graphitic petals/Ni—Co—Mn triple hydroxide nanoneedle structure at low magnification (the inset shows large-scale coverage of graphitic petals/Ni—Co—Mn triple hydroxide nanoneedles on carbon cloth); (FIG. 11B) an SEM image of carbon cloth/graphitic petals/Ni—Co—Mn triple hydroxide nanoneedle structure at high magnification; (FIG. 11C) a TEM image of a carbon cloth/graphitic petals/Ni—Co—Mn triple hydroxide nanoneedle structure; (FIG. 11D) a high-resolution TEM image displaying the porous structure of Ni—Co—Mn triple hydroxide nanoneedles; (FIG. 11E) a high-angle annular dark field (HAADF) scanning TEM image; and (FIGS. 11F-11J) elemental mapping showing uniform spatial distribution of mapped elements in the nanoneedles: (FIG. 11F) to (FIG. 11J) correspond to C, Co, Ni, Mn and O maps, respectively.

FIGS. 12A through 12F are SEM images of: (FIG. 12A) a carbon cloth at low magnification (the inset shows the surface of a single carbon fiber); (FIG. 12B) carbon fibers at low magnification; (FIG. 12C) uniform and large-scale coverage of graphitic petals on carbon fibers; (FIG. 12D) carbon fibers covered by graphitic petals at higher magnification; (FIG. 12E) high-magnification SEM image of graphitic petals with sharp edges; and (FIG. 12F) cross-sectional SEM image of carbon fibers covered by graphitic petals (the inset displays the interface between carbon fiber and graphitic petals).

FIGS. 13A through 13F are SEM images of Ni—Co—Mn triple hydroxide nanoneedles prepared in a series of precursor solutions with different Ni:Co:Mn molar ratios on Ni foam including: (FIG. 13A-13B) low and high magnification, respectively, of a Ni:Co:Mn molar ratio of 1:1:1; (FIG. 13C-13D) low and high magnification, respectively, of a Ni:Co:Mn molar ratio of 1:1:2; and (FIG. 13E-13F) low and high magnification, respectively, of a Ni:Co:Mn molar ratio of 1:1:5.

FIGS. 14A through 14F are SEM images of Ni—Co—Mn triple hydroxide nanoneedles prepared in a series of precursor solutions with different Ni:Co:Mn molar ratios on a carbon cloth/graphitic petal structure including: (FIG. 14A-14B) low and high magnification, respectively, of a Ni:Co:Mn molar ratio of 1:1:1; (FIG. 14C-14D) low and high magnification, respectively, of a Ni:Co:Mn molar ratio of 1:1:2; and (FIG. 14E-14F) low and high magnification, respectively, of a Ni:Co:Mn molar ratio of 1:1:5.

FIGS. 15A and 15B are SEM images of Ni—Co—Mn triple hydroxide nanoneedles grown on pure carbon cloth at low and high-magnification, respectively.

FIGS. 16A through 16F include (FIG. 16A) a XRD pattern of carbon cloth/graphitic petals/Ni—Co—Mn triple hydroxide nanoneedles; and (FIGS. 16B-16F) high-resolution XPS spectra of C 1s; O 1s; Ni 2p; Co 2p; and Mn 2p, respectively.

FIG. 17 is a comparative Raman spectra of a reference Ni—Co double hydroxide and Ni—Co—Mn triple hydroxide.

FIGS. 18A through 18D include: (FIG. 18A) cyclic voltammograms (CVs) of a carbon cloth/graphitic petals/Ni—Co—Mn triple hydroxide nanoneedle hybrid electrode in a three-electrode cell with 2 M KOH aqueous solution; (FIG. 18B) galvanostatic charge/discharge curves of a carbon cloth/graphitic petals/Ni—Co—Mn triple hydroxide nanoneedle hybrid electrode at low current densities; (FIG. 18C) specific capacitances as a function of current density of a carbon cloth/graphitic petals/Ni—Co—Mn triple hydroxide nanoneedle, carbon cloth/Ni—Co—Mn triple hydroxide nanoneedle, and carbon cloth/graphitic petals/Ni—Co double hydroxide hybrid electrodes; and (FIG. 18D) capacitance retention of a carbon cloth/graphitic petals/Ni—Co—Mn triple hydroxide nanoneedle, a carbon cloth/Ni—Co—Mn triple hydroxide nanoneedle, and carbon cloth/graphitic petals/Ni—Co double hydroxide hybrid electrodes.

FIGS. 19A through 19D include: (FIG. 19A) a Nyquist plot for Ni—Co—Mn triple hydroxide hybrid electrodes; (FIG. 19B) a specific energy and power density (Ragone plot) of a carbon cloth/graphitic petals/Ni—Co—Mn triple hydroxide nanoneedle, a carbon cloth/Ni—Co—Mn triple hydroxide nanoneedle, and a carbon cloth/graphitic petals/Ni—Co double hydroxide hybrid electrodes evaluated at different charge/discharge rates (current densities); (FIG. 19C) capacitance retention and coulombic efficiencies during a charge/discharge cyclic stability test at a current density of 10 mA cm⁻²; and (FIG. 19D) a radar plot to summarize the electrochemical performance of the carbon cloth/graphitic petals/Ni—Co—Mn triple hydroxide nanoneedle (indicated by a red color), carbon cloth/Ni—Co—Mn triple hydroxide nanoneedle (green color), and carbon cloth/graphitic petals/Ni—Co double hydroxide (blue color) hybrid electrodes.

FIGS. 20A through 20D contain plots representative of electrochemical performance of two-terminal asymmetric supercapacitor devices (carbon cloth/graphitic petals//carbon cloth/graphitic petals/Ni—Co—Mn triple hydroxide nanoneedles) in 2 M KOH aqueous electrolyte solution.

### DETAILED DESCRIPTION OF THE INVENTION

The present invention generally relates to the field of pseudocapacitive electrode materials for energy storage systems such as supercapacitors. In accordance with aspects of this invention, various pseudocapacitive electrode materials are provided, particularly multi-component metal oxides/hydroxides containing transition metal elements (e.g., Ni, Co, Mn), as well as various substrates for supporting the electrode materials, and various morphologies for both the electrode materials and substrates. Although the invention will be explained in regards to specific combinations of materials and morphologies, the invention is not limited to the examples disclosed. For example, it is within the scope of the invention to provide any combination of the materials and morphologies of the materials and substrates disclosed herein.

Pseudocapacitive electrode materials used herein include bi- and tri-component metal oxides/hydroxides containing transition metal elements (e.g., Ni, Co, Mn). Transition metal oxides and hydroxides possess variable valencies, thus possessing multiple oxidation states that enable rich redox reactions for pseudocapacitance generation. However, this does not necessarily mean that more components in a metal hydroxides lead to higher capacitance, as adding additional components will change the crystal structure and dominant valencies of the material.

It is believed that determinative factors for obtaining desirable electrodes include (I) elements with rich redox states, and (ii) a uniform distribution of the elements. Generally, more accessible redox states in the metal components of pseudocapacitive electrode materials lead to higher pseudocapacitance. Transition metal elements such as Ni, Co, and Mn are endowed with rich redox states and suitable as the metal components for metal oxide/hydroxide pesudocapacitive electrodes. The balanced distribution of metal components in the metal oxides/hydroxides facilitates higher pseudocapacitance from surface redox reactions with electrolytes.

For instance, compared to single-component metal oxides/hydroxides, two-component metal oxides/hydroxides with more feasible oxidation states are introduced to further enhance pseudocapacitance. Among these two-component metal oxides/hydroxides, NiCo₂O₄ has attracted particular attention in recent years as a pseudocapacitive electrode material. Many other combinations of transition metal oxides, such as Co—Mo, Ni—Mo, Mn—Fe, Mn—Mo, Co—Mo, Ni—Mo, V—Mo oxides/hydroxides, can also act as pseudocapacitive electrodes. These electrodes exhibit noticeably higher pseudocapacitance than that of single-component metal oxide/hydroxides. Investigations leading to the present invention indicated that three-component metal (tri-metal) oxides/hydroxides provide significant improvements over previously known single- and bi-metal oxides/hydroxides. As such, preferred embodiments of the invention include homogeneous bi- or tri-metal oxides/hydroxides with a unitary structure. As a nonlimiting example, Ni—Co—Mn triple hydroxide (NCMTH) nanostructures have been observed to provide high-rate and long-cycle-life pseudocapacitive electrodes. As with double metal formations, other metallic elements can act as suitable pseudocapacitive enhancers, including Mo, Fe, and V. Furthermore, structural and compositional characteristics of NCMTHs indicate that the multi-component metal elements distribute homogeneously within the NCMTHs.

The multi-component metal oxides/hydroxides may have a variety of different morphologies, as nonlimiting examples, nanoscale structures such as nanosheets, nanotubes, nanoneedles, nanowires, nanopetals, etc., that may be located on a variety of different substrates (e.g., carbon cloth, Ni foam, carbon nanofibers, nanopetals, etc.). As used herein, “nanoscale” refers to a structure having at least one dimension of 100 nanometers or less (e.g., 0.1-100 nm), “nanosheet” refers to a two-dimensional (2D) structure over a limited plane; “nanotube” refers to a one-dimensional (1D) hollow tube-like structure; “nanoneedle” refers to a (1D) needle-like structure having a sharp tip and a larger base that define a conical shape; “nanowire” refers to a (1D) solid tube-like structure, and “nanopetal” refers to (2D) structures having sharp edges protruding from a larger body.

Electrode materials, substrate materials, and combinations of morphologies of the electrode and substrate materials may be chosen based on a multitude of factors. Preferably, the electrode materials form a nanoscale homogeneous structure with uniform distributions of elements with enhanced oxidation states and synergistic effects of the multi-metal components in the electrodes. High rate capability may be dependant on the nanostructures of the electrode material and the substrate, the combination of the two structures, the amount of surface area to volume of the electrode, the fabrication process, the conductivity of the electrodes, and a contiguous transition between the electrode material and the substrate with crystalline continuity.

As examples, decreasing the weight and thickness of the substrate while increasing its surface area may improve the utilization efficiency of pesudocapacitive materials and overall electrochemical performance of electrodes (e.g., rate capability, energy and power density). Preferably, the substrate comprises numerous sharp edges within the structure of the substrate. These edges may not only increase the surface area but also serve as nanosubstrates with a high density of sharp edges for the metal hydroxide to cover. Moreover, thin protruding edges may accelerate ion diffusion due to low energy barriers, improve mechanical contact between the pesudocapacitive material and current collector, and most importantly enhance charge transfer efficiency to fully exploit the excellent pesudocapacitive properties of the electrode materials by providing a direct path for efficient electron transport. Increased porosity of the electrode material may facilitate electrolyte ion diffusion on/into the surface of the active pesudocapacitive material (enabling fast redox reactions) and further enhance charge storage in the electrodes by increasing the accessible surface area.

The electrodes may be formed by any suitable process known in the art, such as but not limited to electrodeposition and hydrothermal deposition. Nonlimiting examples of electrode morphologies in accordance with aspects of the invention include arrays of multi-component metal oxide or hydroxide nanoneedles or nanopetals on a foam or cloth substrate. Particular examples include an array of Ni—Co—Mn oxide nanoneedles on an Ni foam substrate, an array of Ni—Co hydroxide nanopetals on a graphene petal foam substrate, and an array of Ni—Co—Mn oxide nanoneedles on a graphitic petal carbon cloth substrate. The term graphitic is used herein as referring to structures that comprise layers of graphene.

Investigations leading to the present invention are described hereinafter with reference to various nonlimiting examples of pseudocapacitive electrode materials in accordance with aspects of the present invention.

In a first investigation, Ni—Co—Mn oxide nanoneedles were synthesized on an nickel foam substrate. The Ni foam (5 mm×14 mm in a rectangular shape) was immersed in a 3 M HCl solution for 5 minutes to remove a surface oxide layer. 1.455 g Co(NO₃)₂.6H₂O, 1.45 g Ni(NO₃)₂.6H₂O, 1.255 g Mn(NO₃)₂.4H₂O, and 0.9 g urea were dissolved in 70 mL of deionized water at room temperature to form a light pink solution. The solution with a volume of 14 mL was then transferred into a 20 mL Teflon-lined stainless steel autoclave with the Ni foam substrate. The autoclave was maintained at 135° C. for 8 hours in an electric oven and subsequently cooled down to room temperature in air. The samples were carefully washed many times and sonicated to remove the excessive metal oxides piled on the Ni ligament surface. To obtain the Ni—Co—Mn oxide, as-grown hydroxide precursor nanoneedle arrays on the Ni substrate were placed in a quartz tube furnace filled with a steady N₂ flow and heating rate of 2° C./min, annealed at 300° C. for 2 hours, and cooled to room temperature naturally in a steady N₂ flow.

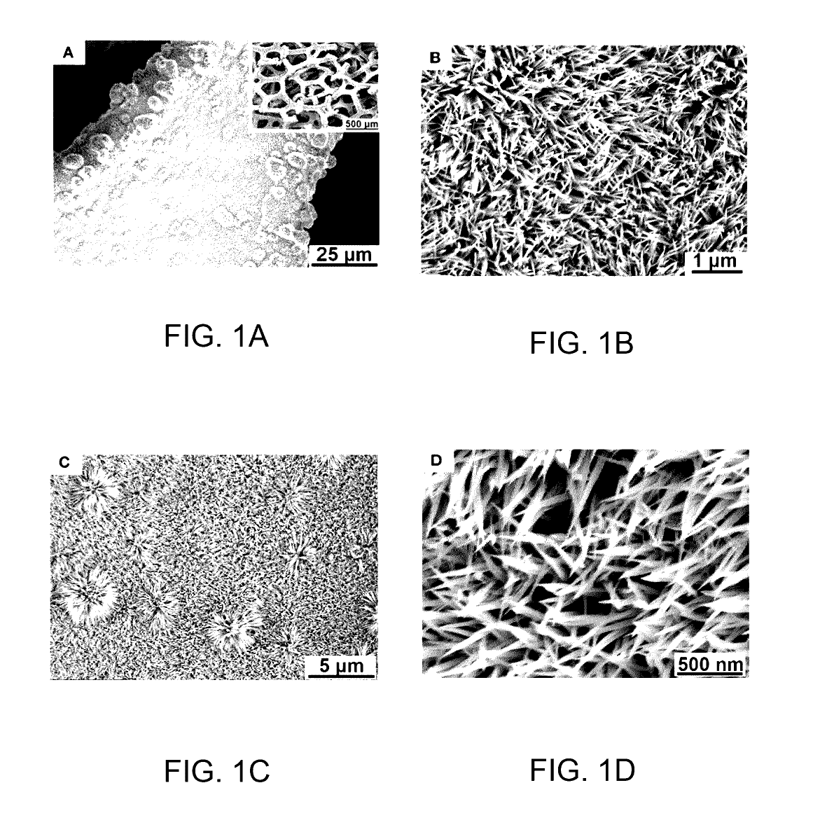

FIGS. 1A and 1B are scanning electron microscopy (SEM) images of the Ni—Co—Mn hydroxide precursor nanostructures on Ni foam. As shown in FIG. 1A, the Ni—Co—Mn precursor nanostructures grow uniformly on the substrate to form an array structure over a large area (see FIG. 1A inset). These uniform nanostructures with needle-like shapes protrude roughly perpendicularly from the Ni foam ligaments (see FIG. 1B). After annealing, the array structure and the nanoneedle shape are fully retained as shown in FIGS. 1C and 1D. The high-resolution SEM image in FIG. 1D indicates that the nanoneedle tip diameters can be as small as a few nanometers.

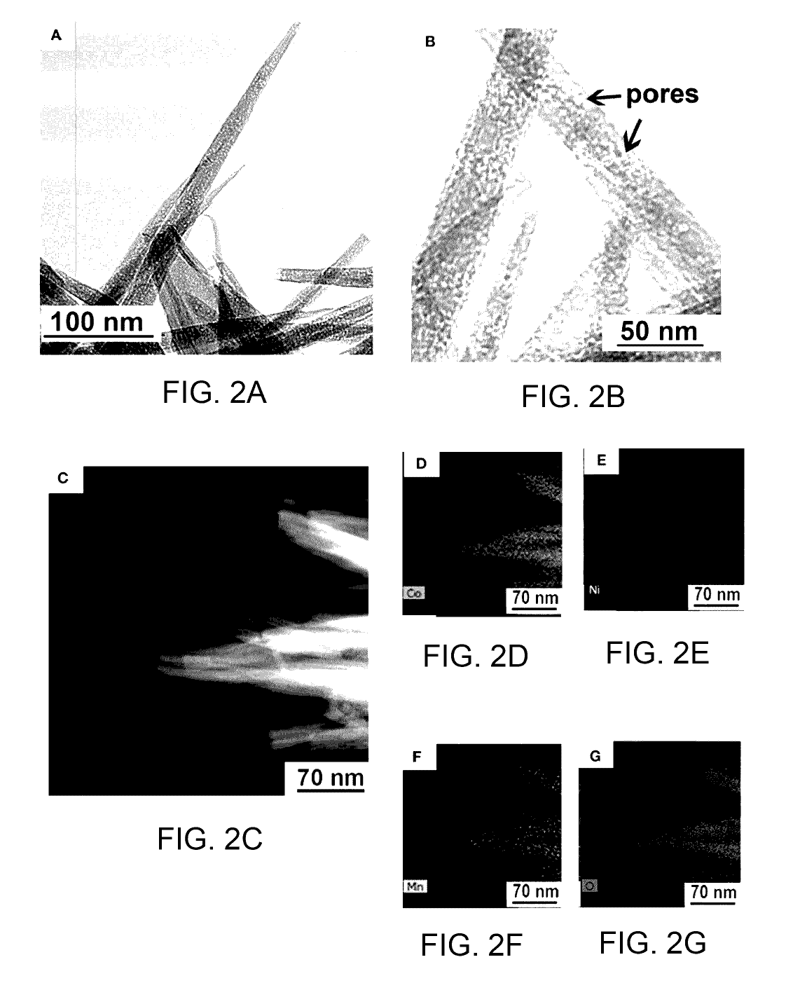

These Ni—Co—Mn oxide nanoneedles have been further characterized by TEM as shown in FIGS. 2A through 2G. The needle-like Ni—Co—Mn oxide with tip diameters ranging from a few nanometers to several tens of nanometers can be clearly seen in FIG. 2A, in agreement with the foregoing SEM results represented in FIGS. 1A through 1D. Notably, the high-resolution TEM image in FIG. 2B reveals a porous nature of nanoneedles. Such a porous structure is beneficial in facilitating electrolyte ion diffusion to the surface of electrodes for fast redox reactions and double-layer charge/discharge as well as increasing the electrode/electrolyte contact area, and consequently enhancing the electrochemical performance. The TEM elemental maps (FIGS. 2B-F) confirm the homogenous distribution of Ni, Co, Mn, and O elements in the unitary nanoneedle structure. EDX mapping indicated that the atomic ratio of Ni:Co:Mn in the as-prepared Ni—Co—Mn oxide nanoneedles was estimated to be 5:5:1. However, these rations are tunable by adjusting the concentrations of raw chemicals in the precursor solution during the preparation process.

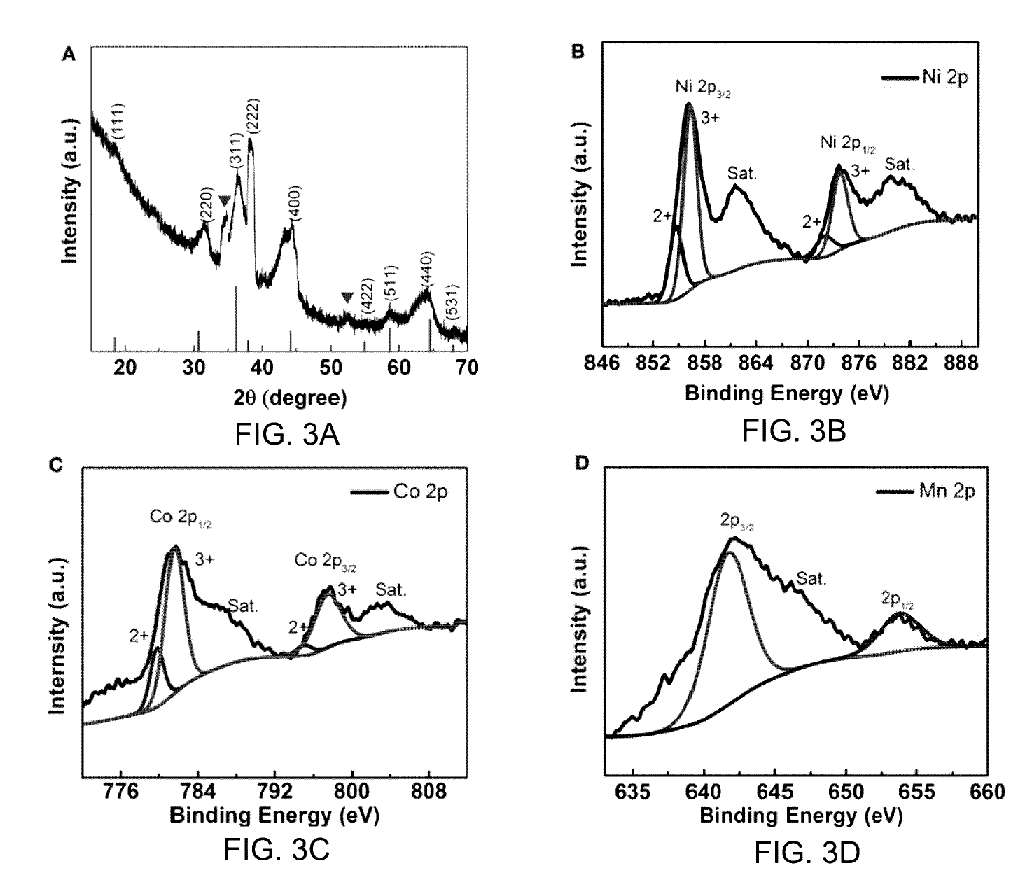

FIGS. 3A through 3D represent XRD and XPS results indicating the structure and chemistry of the Ni—Co—Mn nanoneedles. Based on these analyses, the surface of the as-prepared Ni—Co—Mn oxide possessed a composition containing Ni²⁺, Ni³⁺, Co²⁺, Co³⁺, Mn²⁺, and Mn³⁺.

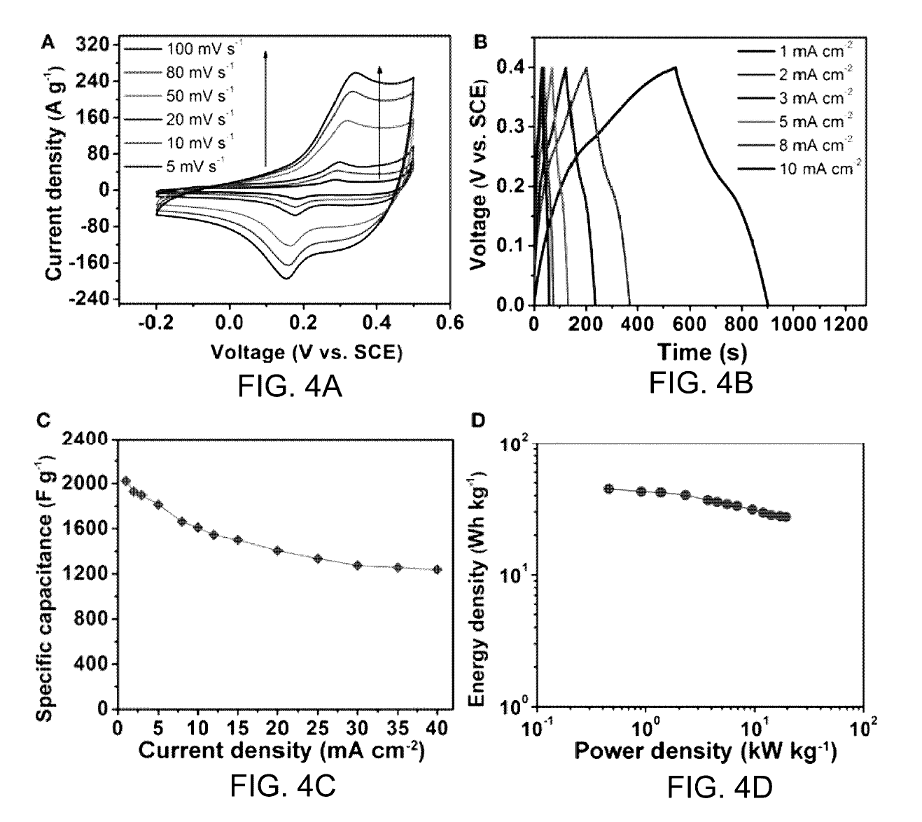

FIGS. 4A through 4D provide characteristic electrochemical performance curves of the multi-component metal oxide. FIG. 4A shows the cyclic voltammetry (CV) results of the Ni—Co—Mn oxide (a mass of approximately 0.11 mg, corresponding to a density of about 0.5 mg cm⁻²) at voltage scan rates from 2 to 100 mV s⁻¹ with a voltage window from −0.2 to 0.5 V vs. SCE in 2 M KOH. Distinct redox peaks exist in the scanned CV curves at all scan rates, and these are primarily associated with faradaic redox reactions related to M—O/M—O—OH (M represents Ni, Co, or Mn) associated with OH⁻ anions.

FIG. 4B shows the galvanostatic charge/discharge profiles at different current densities ranging from 1 to 40 mA cm⁻² which represent a relatively symmetric shape. Voltage plateaus in discharge curves appear at around 0.2V, which is consistent with the CV curves of FIG. 4A. Specific capacitances (using an active material mass basis) are plotted as a function of discharge current densities in FIG. 4C. Notably, the specific capacitance of the Ni—Co—Mn oxide electrodes is greater than 2000 Fg⁻¹ at a discharge current density of 1 mA cm⁻², which is more than three times higher than that of NiCo₂O₄ at the same current density. A significant enhancement in charge storage was also observed in the comparative CV curves of the two oxide electrodes.

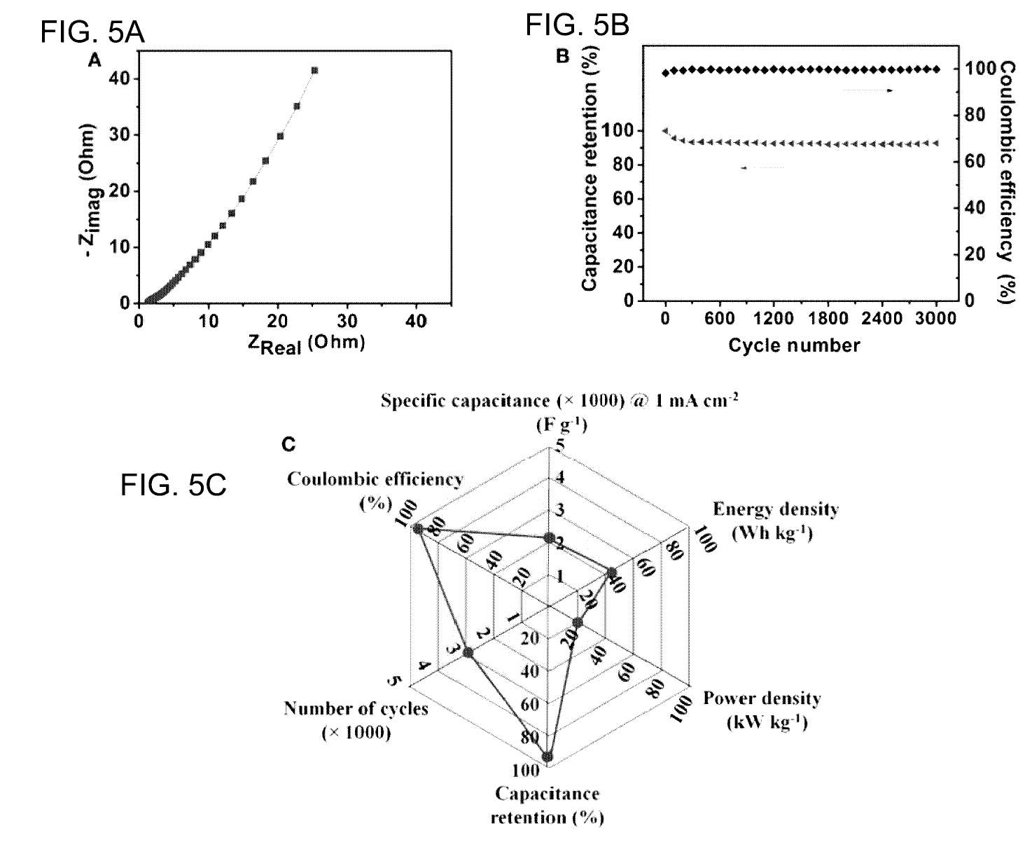

This significant increase in specific capacitance can be attributed to the homogeneous structure of the metal oxide with uniform distributions of Ni, Co, and Mn elements, increased number of oxidation states and synergistic effects of the ternary metal components in the electrodes. The specific capacitance of the multi-component metal oxide dropped to about 1250 Fg⁻¹ at a high current density of 40 mA cm⁻² (corresponding to about 80 Ag⁻¹), indicating a fairly good rate capability. FIG. 4D shows a Ragone plot for the Ni—Co—Mn oxide electrode at different current densities. The energy density decreases from 45 to 27.5 Wh kg⁻¹, while the average power density increases from 0.9 to 19.5 kW kg⁻¹ as the galvanostatic charge/discharge current increases from 1 to 40 mA cm⁻². These values are more promising than the reported energy and power densities of NiCo₂O₄ nanowires (energy and power densities less than 20 Wh kg⁻¹ and 7 kW kg⁻¹, respectively). FIG. 5A shows a Nyquist plot for the Ni—Co—Mn oxide nanoneedle electrodes recorded from 0.1 Hz to 1 MHZ. The equivalent series resistance (ESR) value calculated from FIG. 5A for the Ni—Co—Mn oxide electrodes is as low as 1.29Ω. Notably, the Nyquist plot shows no characteristic circular curvature in the high frequency region, indicating that the charge transfer resistance in the electrodes during charge/discharge process is negligible, which suggests very low electrical resistivity of the material and high charge transfer efficiency at the interface of the Ni—Co—Mn oxide electrodes. Moreover, the linear behavior in the low frequency range is indicative of capacitive behavior of the electrodes.

Long-term cycle life is one of the most critical issues concerning metal oxide-based supercapacitor electrodes. FIG. 5B shows the specific capacitance retention as a function of cycle number. The multi-component metal oxide electrode showed about 7 percent loss in specific capacitance over 3000 charge/discharge cycles at a current density of 10 mA cm⁻² and high coulombic efficiencies (>99%), indicating good long-term cyclic stability and high charge storage/utilization efficiencies. No noticeable changes in the morphology of the nanoneedle electrodes were observed.

In view of the results shown in FIGS. 1A through 5C, the homogenous Ni—Co—Mn oxide on Ni foam is believed to be a suitable material for high-performance supercapacitor electrode applications. The electrode exhibited a specific capacitance of 2023 Fg⁻¹ at 1 mA/cm⁻², three times higher than that of NiCo₂O₄ in the control experiments, excellent long-term stability, and low IR. Such intriguing pesudocapacitive behavior is attributed to the homogeneous structure of the metal oxide with uniform distributions of Ni, Co, and Mn elements, enhanced oxidation states, and synergistic effects of the components in the electrodes. This enhancement can be further maximized by adjusting the ratios of these elements in the oxides. The multi-component electrode in this investigation was further observed to exhibit excellent thermal stability and repeatability over a wide temperature range (4° C. to 80° C.).

In a second investigation, a hierarchical structure of Ni—Co hydroxide nanopetals (NCHPs) were synthesized on a thin free-standing graphene petal foam (GPF) substrate by a two-step process and characterized for pseudocapacitive electrodes. First, a monolithic and lightweight graphene petal foam was synthesized by growing graphitic petals (GPs) via catalyst-free microwave plasma chemical vapor deposition (MPCVD) on a three-dimensional Ni foam, followed by chemical etching of Ni ligaments. The graphitic petals are generally comprise at least a few layers of graphene that grow roughly perpendicularly to a substrate over a large surface area. Second, uniformly distributed NCHPs were electrodeposited on the freestanding thin GPF nanosubstrate to form a hierarchical petal-on-petal structure (with smaller NCHPs decorating larger graphene nanopetals).

FIG. 6 schematically illustrates a hierarchical petal-on-petal structure of NCHPs on GPF. Free-standing thin GPF, comprising a highly conductive and ultralight interconnected three-dimensional graphene petal networks, provided an efficient and mechanically robust current collector/nanosubstrate for the pesudocapacitive metal hydroxide. Hollow micro-channels were achieved by etching Ni ligaments to augment the accessible surface area of the hybrid electrodes to electrolytes, and more importantly to reduce ion diffusion resistance, shorten ion diffusion lengths, and thereby improve rate capabilities. Vertically standing and highly graphitic GPs within the GPF structure, compared to the horizontal graphene layers in graphene foams, not only significantly increase the surface area but also serve as nanosubstrates with a high density of sharp edges for the metal hydroxide to cover. Moreover, these thin protruding GP edges are believed to significantly accelerate ion diffusion rates due to low energy barriers. This hierarchical petal-on-petal structure is believed to allow rapid access of electrolyte ions to the surfaces of NCHPs with short electron and ion diffusion paths, leading to faster kinetics and higher rate capability.

The GPF was synthesized on a Ni foam (MTI Corp., thickness: 1.6 mm, purity >99.99%, surface density: 350±30 g m⁻² and porosity: ≧95%) was used as a three-dimensional template to grow GPs in a MPCVD system. Before GP growth, the Ni foam was compressed to a thickness of approx. 200 μm as the substrate. The substrate, elevated 8 mm above a Mo puck by ceramic spacers, was subsequently subjected to MPCVD conditions of H₂ (50 sccm) and CH₄ (10 sccm) as the primary feed gases at 20 Torr total pressure and 500 W plasma power. The GP growth time was 25 minutes. After the MPCVD process on the Ni foam, uniform and dense GPs were observed to grow roughly perpendicularly on the relatively smooth Ni ligament surface, with typical widths of a single, unwrinkled two-dimensional petal ranging from 100 nm to 500 nm and thicknesses of a few nanometers. These nanopetals were highly graphitic and hydrophobic with negligible oxygen content.

The Ni foams fully covered with graphite petals were immersed in a PMMA solution (4 wt % in ethyl lactate), and then baked at 180° C. for 30 minutes. The PMMA-protected Ni foam/graphitic petals were then immersed in a 3 M HCl solution at 80° C. overnight to completely dissolve the nickel ligaments to obtain GPF/PMMA composite. Finally, free-standing GPFs were obtained by dissolving the PMMA with hot acetone at 55° C. Prior to the electrodeposition of NCHPs on the foam nanosubstrate, GPFs are electrochemically activated in a three-electrode system at a constant potential of 1.9 V for 10 minutes in 1 M H₂SO₄ solution at room temperature, and then thoroughly rinsed with deionized water until pH=7.

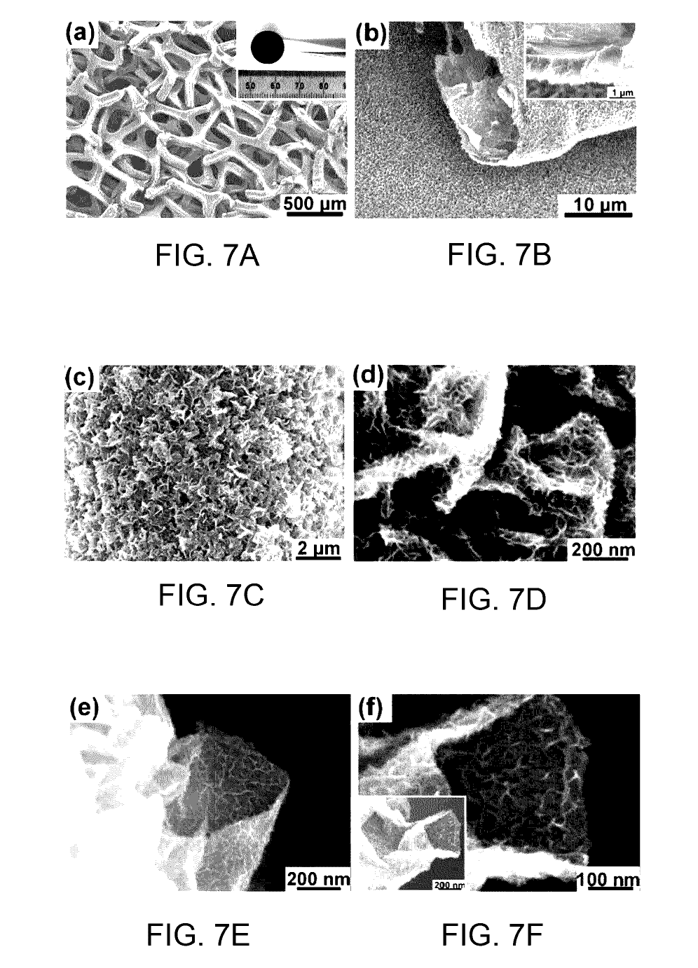

After etching the Ni ligaments, the freestanding GPF was obtained with an interconnected three-dimensional scaffold structure inherited from the Ni foam template. Ligaments consisting of solely graphene nanostructures were apparent, resembling the configuration of Ni ligaments, as shown in FIG. 7A. GPFs can be fabricated in various shapes (e.g., circular and rectangular) depending on that of the Ni foam template (see the inset in FIG. 7A). The thickness of the GPF is determined by the Ni foam template (typically hundreds of microns). After etching the Ni ligaments, hollow channels formed with thin vertical GPs (hundreds of nanometers) atop continuous thin, tubular graphitic layers (tens of nanometers) as walls, with a total thickness of approximately 1 micron (see FIG. 7B), which is tunable by adjusting the GP growth time in the MPCVD process.

The micro-conduit structure with hollow channels increases accessible electrode surface area to the electrolyte and facilitates fast diffusion of ions during charge/discharge processes, enabling high charge storage and high rate capabilities even with a very thin GPF thickness. These GPFs with hollow channels are ultralight, with a mass density of about 40 mg cm⁻³ (depending on the GP growth time), and high electrical conductivity (>35 S cm⁻¹), more than 3 times higher than that of graphene foam (10 S cm⁻¹). This high electrical conductivity was attributed to the continuous tubular graphitic layer beneath the graphitic petals that forms during the initial growth stage before the plasma-enabled vertical graphene petal growth. Notably, the mechanical robustness of GPFs is a prerequisite for their use as a stable current collector with high electrical conductivity.

The NCHPs were prepared on the GPF by an electrodeposition method. The electrodeposition was conducted using a three-electrode system consisting of the GPF as the working electrode, a Pt mesh as the counter electrode and a saturated calomel electrode (SCE) as the reference electrode. The NCHP was electrodeposited upon GPF at a constant potential of −1.0 V vs. SCE in the aqueous solution containing 0.1 M Ni(NO)₃ and 0.03 M Co(NO)₃ at ambient temperature. The electrodeposition duration was 0.5, 1, 2.5, 3, 5 and 8 minutes.

After the metal hydroxide electrodeposition processes, the NCHPs uniformly covered the GPF skeleton over a large scale (see FIG. 7C). At the local scale, NCHPs grew densely and homogenously on the surface of GPs in GPF ligaments (see FIG. 7D). High-magnification SEM images in FIGS. 7E and 7F indicate that smaller NCHPs with lateral sizes of several tens of nanometers protrude perpendicularly from the surface of larger GPs with lateral sizes of several hundreds of nanometers. This hierarchical petal-on-petal structure of GPF/NCHPs not only increased accessible surface area while facilitating fast ion transport but also increased the utilization efficiency of the metal hydroxide during charge/discharge processes.

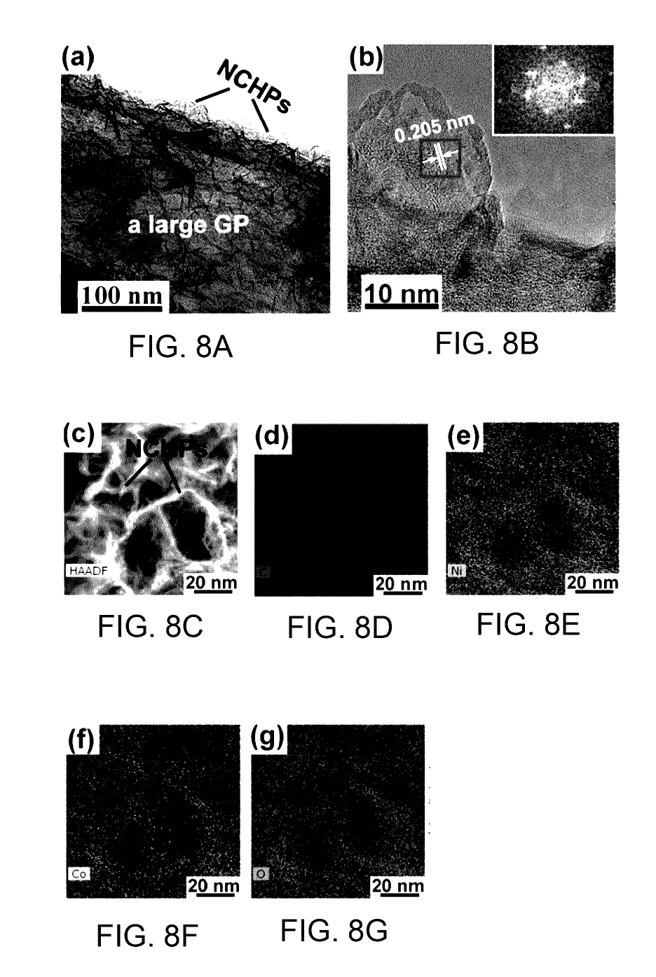

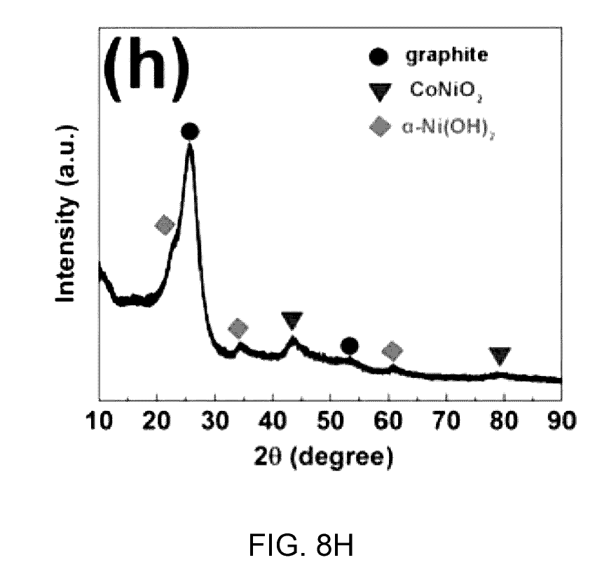

Transmission electron microscopy (TEM) images of the two-dimensional graphene petal cross section indicated their graphitic nature, a thickness of several nanometers, corresponding to less than 50 graphene layers, and an atomic interlayer distance of 0.35 nm. TEM and XRD results for the hierarchical structure of GPF/NCHPs are shown in FIGS. 8A through 8G. After electrodeposition of NCHPs, the GP surface was densely covered by a large amount of smaller thin hydroxide nanopetals with typical lateral sizes of tens of nanometers, as shown in FIG. 8A. The visible dark lines are folded edges, wrinkles, or ripples of NCHPs. As seen from the high-resolution TEM image in FIG. 8B, the spacing between adjacent fringes is calculated to be approximately 0.205 nm, and well-defined diffraction spots were observed from the fast Fourier transform (FFT), suggesting some crystallinity of the hydroxide nanopetals.

Energy dispersive X-ray spectrometry (EDX) elemental mapping of GPF/NCHPs shown in FIGS. 8C-8H revealed the spatial elemental distribution within the hierarchical structure. FIG. 8C contains a high-angle annular dark field (HAADF) scanning TEM image of multiple NCHPs on a magnified portion of a single GP. FIGS. 8D to 8G correspond to C, Ni, Co and O maps, respectively. These spatial elemental mappings not only confirmed the hierarchical petal-on-petal structure of GPF/NCHPs, but more importantly revealed a homogeneous spatial distribution of the mapped elements (Ni, Co and O) in the petal structure. Notably, the element mapping images show that Ni, Co and O were distributed on the surface of GPs and aggregate more on the hydroxide petal edges, indicating that a thin layer of Ni—Co hydroxide was coated on GP surface before the hydroxide petals grow vertically. The relative concentrations of Ni, Co and O elements in the hydroxide were estimated from the EDX elemental mapping. The atomic ratio of Ni:Co:O in the NCHPs was estimated to be 2:1:4.

FIG. 8H contains the XRD pattern of the as-prepared GPF/NCHPs. XPS analysis revealed that some covalent bonds form between C and O, suggesting that robust bonding exists at the interface between the NCHPs and GPs, and this attribute is potentially beneficial in enhancing electron transfer efficiency at the interface and improving long-term cyclic stability during charge/discharge processes.

Because the GPs are hydrophobic by nature, chemical activation to make them hydrophilic is necessary if aqueous electrolytes are to be used in electrochemical characterization. The morphology of the GPs in the foam ligament changed little after the activation, indicating robust mechanical integrity of the graphene petal foams.

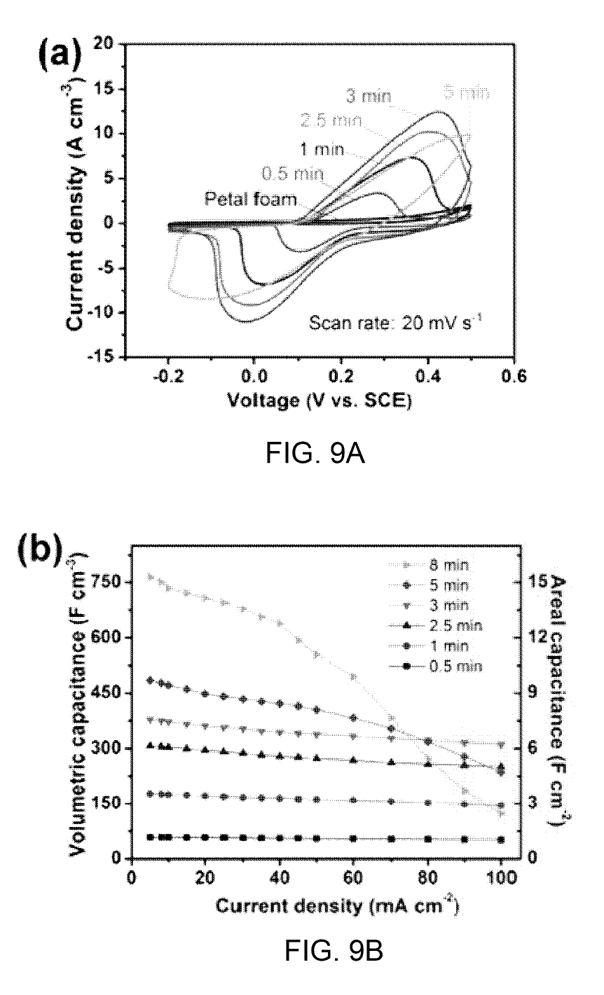

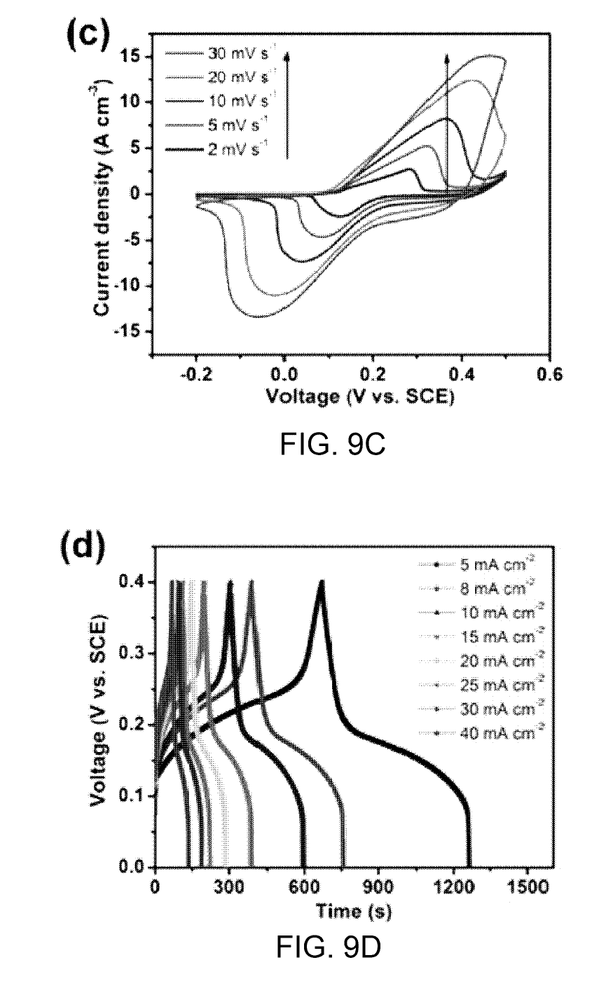

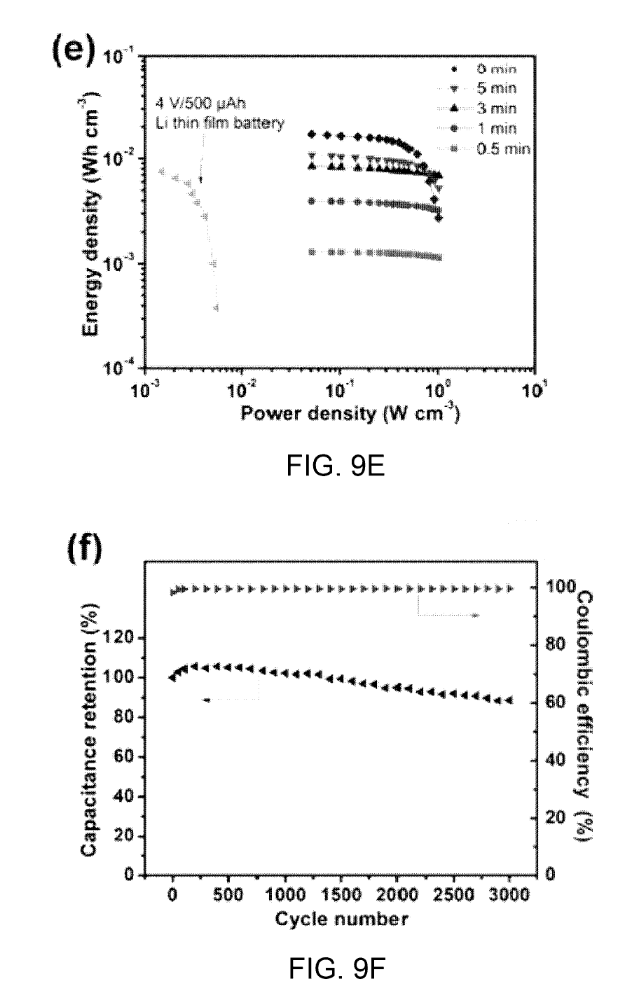

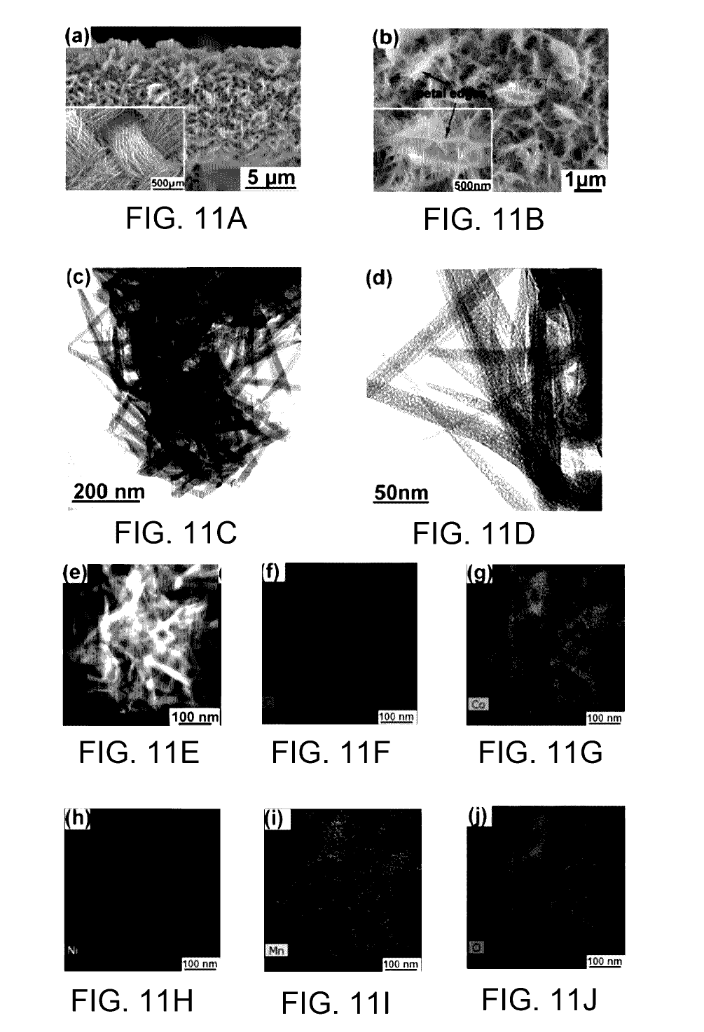

FIGS. 9A through 9F provide characteristic electrochemical performance of the GPF/NCHP electrodes in 2 M KOH aqueous electrolyte. FIG. 9A shows comparative cyclic voltammograms (CVs) of GPF/NCHP electrodes with the foregoing electrodeposition durations of NCHPs (t=0, 0.5, 1, 2.5, 3, and 5 minutes) at a fixed scan rate of 20 mV s⁻. As observed in FIG. 9A, the area of the CV loop corresponding to bare GPF is significantly smaller than those of the electrodes loaded with NCHPs, suggesting a much lower capacitance. No obvious redox peaks are apparent in the CV curves of bare GPF electrodes, indicating that the capacitance is dominated by double-layer formation. Nevertheless, bare GPF still exhibits a much higher capacitance (approx. 0.2 F cm⁻² in alkaline electrolyte at a low current density) than those of graphene foam and graphene nanopetals on carbon fibers (0.076 F cm⁻²). The hybrid electrodes with different NCHP loadings exhibited two distinct redox peaks, corresponding to the redox reactions between NCHPs and alkaline electrolyte. FIG. 9B plots the volumetric and areal capacitances of GPF/NCHP electrodes (a thickness of approx. 200 microns) with different NCHP loadings at different current densities from 5 to 100 mA cm⁻². As shown in FIG. 9B, the volumetric and areal capacitances significantly increase with hydroxide electrodeposition time at low current densities.

At a current density of 5 mA cm⁻², GPF/NCHP electrodes with hydroxide electrodeposition durations of 0.5, 1, 2.5, 3, 5 and 8 minutes exhibited volumetric capacitances of approximately 60, 180, 310, 380, 485, 765 F cm⁻³ (corresponding to areal capacitances of 1.2, 3.6, 6.2, 7.6, 9.7, 15.3 F cm⁻², respectively). These volumetric capacitances are much higher than previously reported state-of-the-art metal hydroxides (typically approx. 94 F cm⁻³), polyaniline-based electrodes (235 F cm⁻³), carbon nanotubes (<16 F cm⁻³), activated carbon (50-100 F cm⁻³), graphene paper (64 F cm⁻³), carbide-derived carbon (180 F cm⁻³, 0.054 F cm⁻²), and sandwich-like MXene/single-walled carbon nanotubes (390 F cm⁻³, about 0.1 F cm⁻²). Meanwhile, the areal capacitances that the graphene petal foam/NCHP electrodes exhibited were also significantly higher than those of reported graphene foam/pseudocapacitive materials in prior work, which typically fall in the range of 0.2 to 3.3 F cm⁻². FIG. 9C shows CV plots from the hybrid GPF/NCHP composite electrode at different scan rates of 2, 5, 10, 20, and 30 mV s⁻¹ with potential windows ranging from −0.2 to 0.5 V vs. SCE in 2 M KOH aqueous electrolyte. FIG. 9D provides the galvanostatic charge/discharge profiles of GPF/NCHP electrodes at different current densities ranging from 5 to 40 mA cm⁻². These constant-current charge/discharge curves display a relatively symmetric shape, indicating high coulombic efficiency and the reversible nature of the redox reactions. The charge/discharge behavior remained symmetric even at a current density as high as 100 mA cm⁻², an indication of good rate stability of the electrodes. FIG. 9E provides a comparative volumetric Ragone plot for GPF/NCHP electrodes with different NCHP electrodeposition durations at different current densities from 5 to 100 mA cm⁻², with comparison to a typical Li-ion thin-film battery.

Long-term life tests over 3000 cycles for the GPF/NCHP hybrid electrode at a current density of 30 mA cm⁻² were conducted using galvanostatic constant-current charge/discharge cycling in a potential window ranging from 0 to 0.4 V. FIG. 9F shows the specific capacitance retention of the GPF/NCHP electrodes as a function of charge/discharge cycle number. The GPF/NCHP electrode exhibits a capacitance retention of approx. 90% over 3000 charge/discharge cycles, indicating excellent long-term cyclic stability that is superior to those of the metal hydroxide-based pseudocapacitive electrodes reported in prior work.

In view of the results summarized in FIGS. 6-9F, a hierarchical structure of Ni—Co hydroxide nanopetals (NCHPs) on the thin free-standing graphene petal foam (GPF) substrate with microscale hollow channels is believed to be suitable for supercapacitor electrode applications. The hierarchical nanoscale structure of smaller NCHPs on larger GPs enabled high charge storage (high capacitance) and fast ion diffusion (high rate capability) in a three-electrode cell. The as-prepared lightweight three-dimensional GPF/NCHP electrodes exhibited volumetric capacitances as high as 765 F cm⁻³ and electrode mass-based capacitances more than an order of magnitude higher than those of Ni foam/NCHP, high rate capabilities and excellent long-term cyclic stability. These results indicated that the utilization efficiency of pesudocapacitive materials and overall electrochemical performance of electrodes (e.g., rate capability, energy and power density) can be further improved if the bulky substrates can be replaced by lightweight and ultrathin nanosubstrates with higher surface area (e.g., all-carbon nanomaterials). The electrochemical performance of the pseudocapacitive electrodes can likely be improved in the future by adjusting factors such as GP growth time and thickness of the graphene petal foam. Moreover, the petal-on-petal structure may also be applicable to other electrochemical systems such as lithium ion batteries, fuel cells and non-enzymatic biosensors, and chemical sensors.

In a second investigation, porous Ni—Co—Mn triple hydroxide (NCMTH) nanoneedle arrays were synthesized on three-dimensional carbon cloth/graphite petal (CC/GP) substrates by a one-step hydrothermal method. The facile one-step hydrothermal process to prepare the hydroxide electrodes is easily controllable without subsequent annealing and promising for potential scalable fabrication.

Carbon cloth substrates (5×10 mm², Fuel Cell Earth type CCP), were elevated 7 mm above a 55-mm-diameter Mo puck by ceramic spacers, and were then subjected to MPCVD conditions of H₂ (50 sccm) and CH₄ (10 sccm) as the primary feed gases at 25 Torr total pressure. The substrates were initially exposed to hydrogen plasma for approximately 2 minutes, during which the plasma power gradually increased from 300 to 550 W. The GP growth time was 15 minutes to ensure the CC substrates were fully covered by GPs.

After GP growth on the carbon cloth substrates, 1.455 g Co(NO₃)₂.6H₂O, 1.45 g Ni(NO₃)₂.6H₂O, 1.255 g Mn(NO₃)₂.4H₂O, and 0.9 g urea were dissolved in 70 mL of deionized water at room temperature to form a light pink solution. The solution with a volume of 14 mL was then transferred into a 20 mL Teflon-lined stainless steel autoclave. A piece of CC/GP substrate (5×10 mm²) was first soaked in alcohol and then washed with purified water (pH=7) thoroughly to fully wet the substrate surface before being transferred to the autoclave filled with the precursor solution. The autoclave was kept at 135° C. for 90 minutes in an electric oven and subsequently cooled to room temperature in air naturally. The samples were washed many times and sonicated to remove excessive metal hydroxides on CC/GPs. After cleaning, the samples were dried in air at a temperature of 80° C. for 3 hours. The areal mass density of the NCMTHs on CC/GP substrates was 0.6 mg cm⁻².

FIG. 10 represents a structure of the NCMTH nanoneedles on CC/GP substrates. Macroscopically woven CC, with gaps between two adjacent carbon fibers ranging from several micrometers to tens of micrometers, provides a flexible and conductive three-dimensional current collector and creates channels for fast and effective electrolyte ion transport with low internal resistance. The three-dimensional CC substrate not only significantly increases the surface area but also serves as a nanosubstrate with numerous sharp edges for the multi-component metal hydroxide. Moreover, these thin protruding GP edges significantly accelerate ion diffusion due to low energy barriers, improve mechanical contact between the pesudocapacitive material and current collector by roughening the carbon fiber surfaces, and most importantly enhance charge transfer efficiency to fully exploit the excellent pesudocapacitive properties of the NCMTHs by providing a direct path for efficient electron transport.

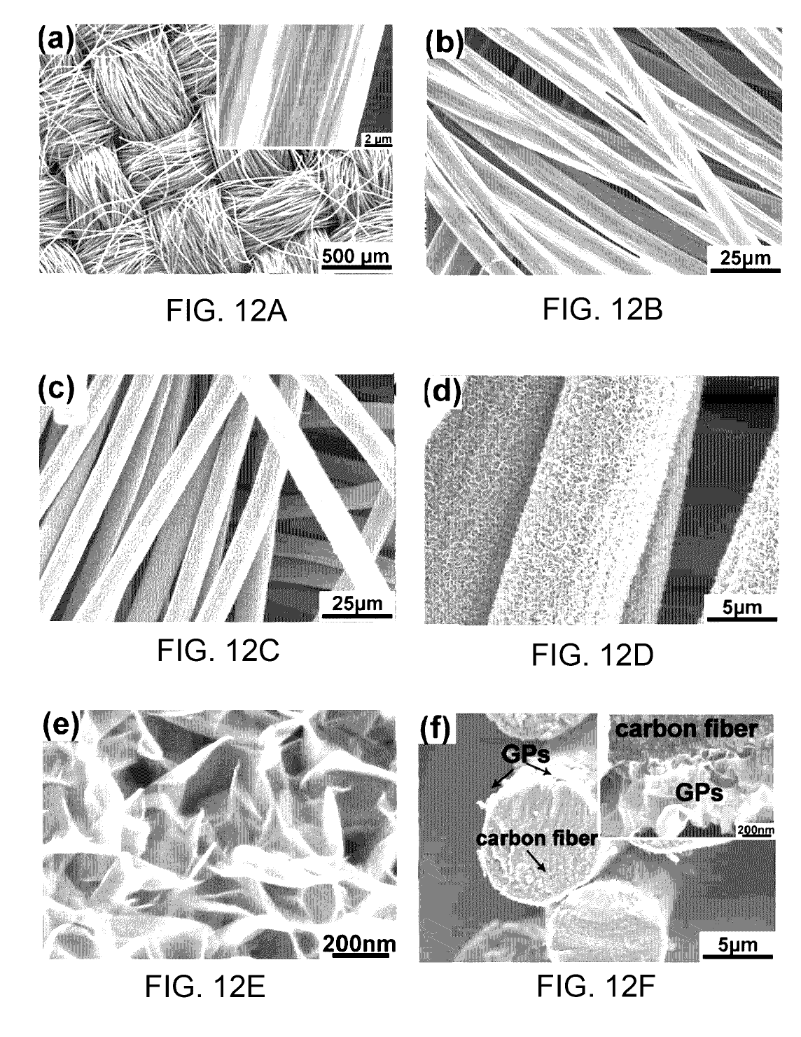

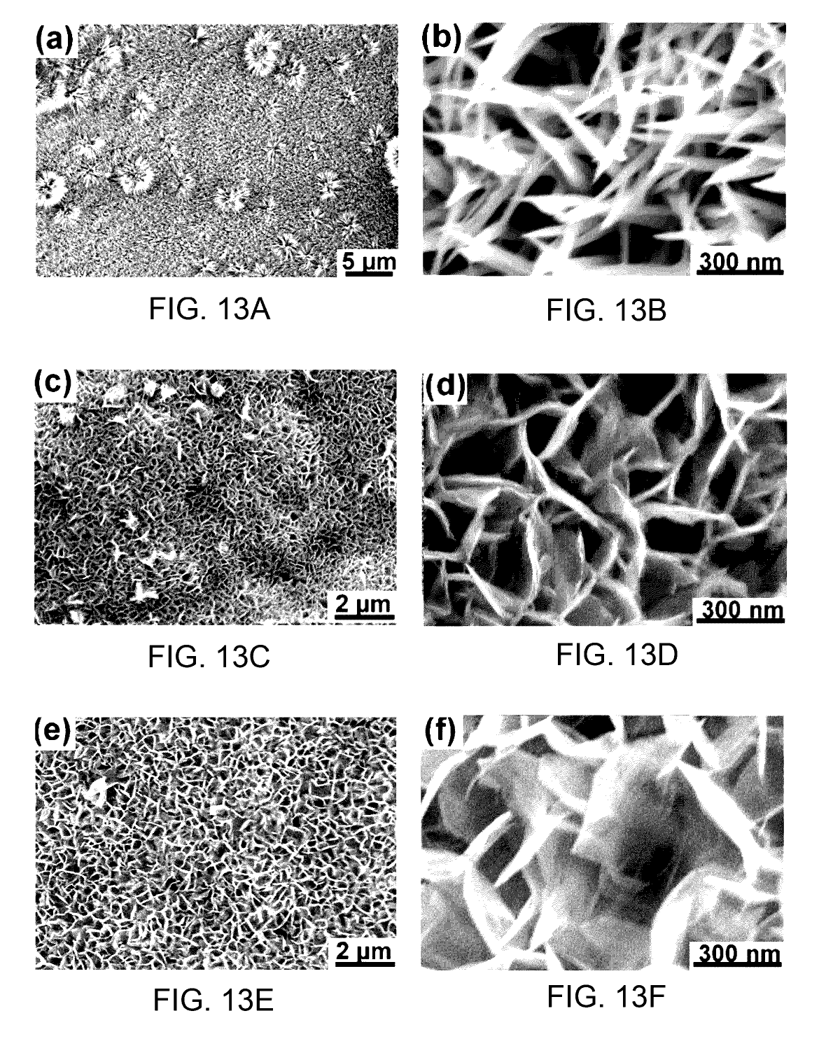

After the one-step microwave plasma growth process, GPs were observed to have grown approximately 400 to 500 nm out from the carbon fiber surface, with a typical width of a single, unwrinkled two-dimensional petal ranging from 100 nm to 400 nm and a thickness of a few nanometers. These GPs were ultra-light, with an areal mass density of about 1 mg cm⁻². FIGS. 11A and 11B contain scanning electron microscopy (SEM) images of uniform NCMTH nanoneedles on CC/GP substrates. As represented in FIG. 11A, NCMTHs grew homogenously on CC/GP substrates over a large scale (see FIG. 11A inset). The high-magnification image in FIG. 11B shows that the protruding NCMTHs with a nanoneedle shape generally grow perpendicularly to GP surfaces. These NCMTH nanoneedles exhibit ultra-sharp tips (diameters as small as a few nanometers) and lengths of hundreds of nanometers. For comparison, uniform and large-scale coverage of GPs without the NCMTHs on carbon fibers are shown in FIGS. 12A-12F. It was further observed that the morphology and structure of NCMTHs could be changed from nanoneedles to nanosheets by increasing the Mn content in the precursor solution. For example, a molar ratio of Ni, Co and Mn of 1:1:1 was observed to obtain NCMTH nanoneedles as represented in FIGS. 11A through 11J while molar ratios of Ni, Co, and Mn, of 1:1:2 and 1:1:5 were observed to obtain nanosheet structures as represented in FIGS. 13C and 13D.

As compared to relatively smooth GP surfaces (FIG. 12E), GPs/NCMTHs showed distinct surface roughness and porosity, with sharp NCMTH nanoneedle tips and GP edges exposed (see FIG. 11B), which are beneficial to fast ion diffusion at high charge/discharge rates. A close-up of NCMTH nanoneedles on a single petal is shown in FIG. 11B inset, in which petal edges can be clearly distinguished. Notably, large channels (gaps between adjacent carbon fibers) created by the three-dimensional CC substrate remained after the GP growth and NCMTH coating on the surface of carbon fibers, providing a prerequisite for fast ion diffusion rate (high rate capability). FIGS. 11C and 11D contain transmission electron microscopy (TEM) images of the GPs/NCMTH nanoneedle structure. FIG. 11C displays many NCMTH nanoneedles decorating a GP. Needles with base diameters of tens of nanometers and tip diameters of a few nanometers are observed, in good agreement with the foregoing SEM results. A high-resolution TEM image in FIG. 11D reveals the porous structure of NCMTH nanoneedles that facilitates electrolyte ion diffusion on/into the surface of the active pesudocapacitive material (enabling fast redox reactions) and further enhances charge storage in the electrodes by increasing the accessible surface area.

Energy dispersive X-ray spectrometry (EDX) elemental mapping images of Gps/NCMTH nanoneedles shown in FIGS. 11E-11J revealed the spatial elemental distribution within the structure. FIG. 11E contains a high-angle annular dark field (HAADF) scanning TEM image of multiple NCMTH nanoneedles on a typical GP. FIGS. 11F to 11J correspond to C, Co, Ni, Mn and O maps, respectively. The atomic ratio of Ni:Co:Mn:O in the NCMTH nanoneedles was estimated to be 5:5:1:20. The ratios can be tuned by adjusting the concentrations of raw chemicals in the precursor solution during the preparation process.

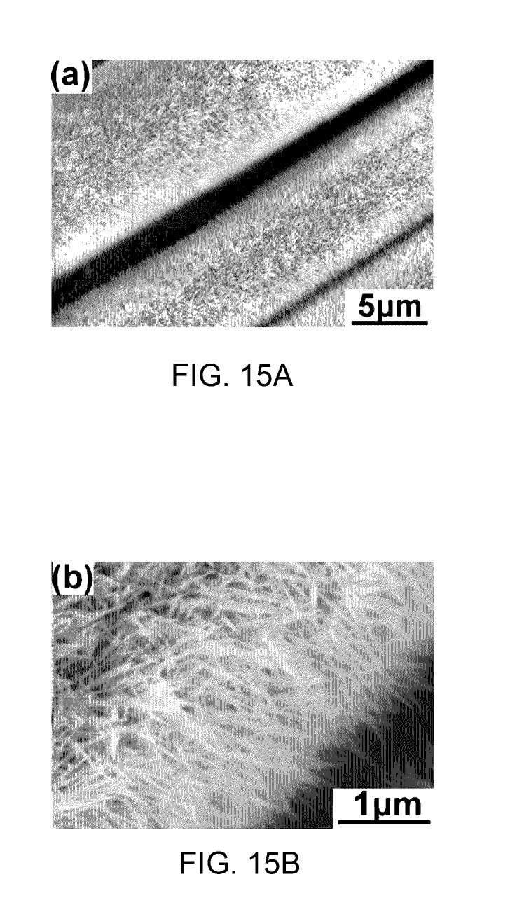

As an alternative, FIGS. 15A and 15B represent NCMTH nanoneedles grown on pure CC substrates in which the NCMTHs also display their ultra-sharp tips, similar to those grown on GPs.

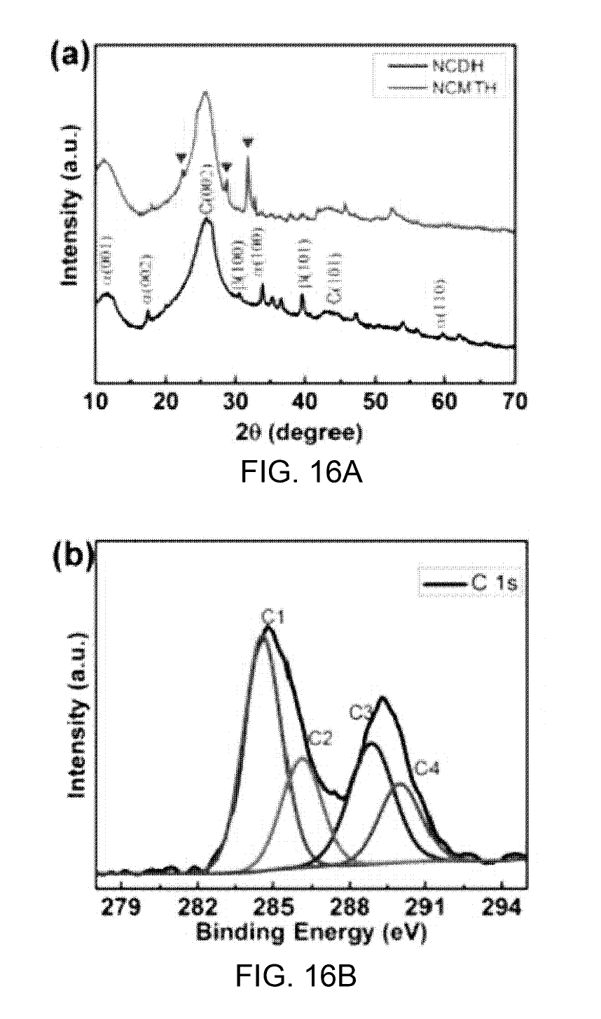

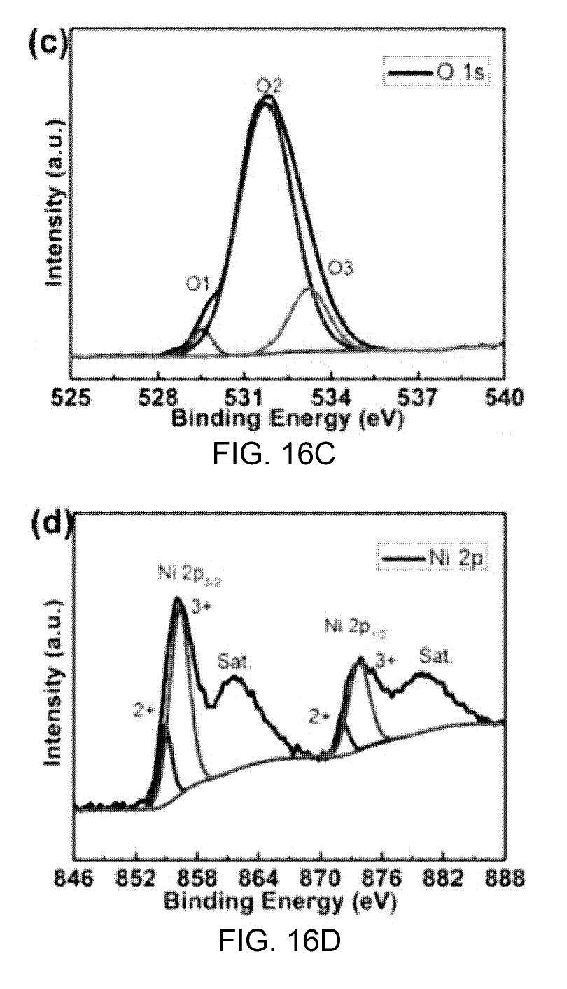

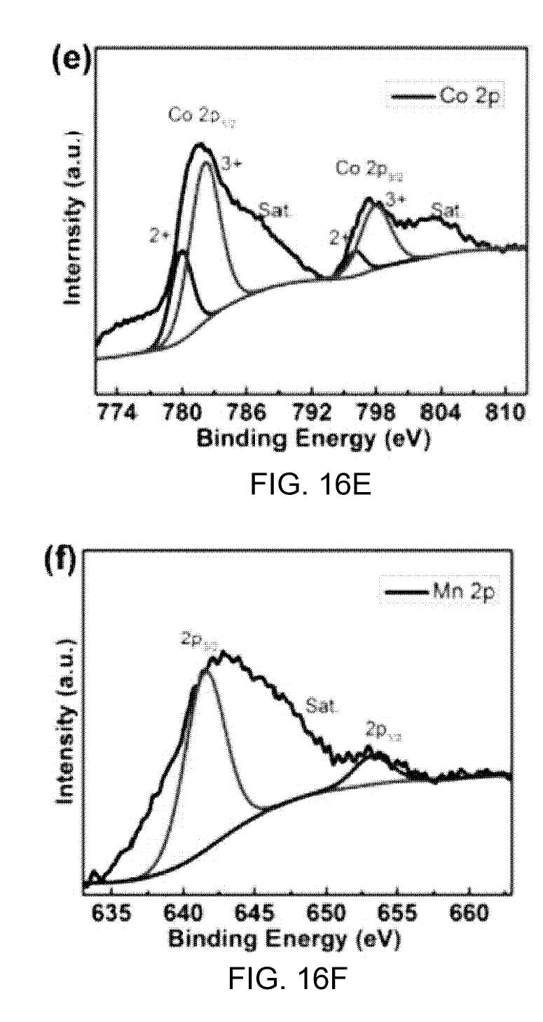

Comparative XRD patterns of CC/GPs/NCMTH and CC/GPs/NCDHs are shown in FIG. 16A. FIGS. 16B-16F contain detailed high-resolution XPS analyses of C 1s, O 1s, Ni 2p, Co 2p and Mn 2p, respectively. Based on the XPS analysis, NCMTH nanoneedles possess a diverse composition of Ni2+, Ni3+, Co2+, Co3+, Mn2+ and Mn on the surface, providing more electroactive sites than single- or double-component metal hydroxides. Raman spectroscopy was also used to characterize the structure of CC/GPs/NCMTHs as shown in FIG. 17.

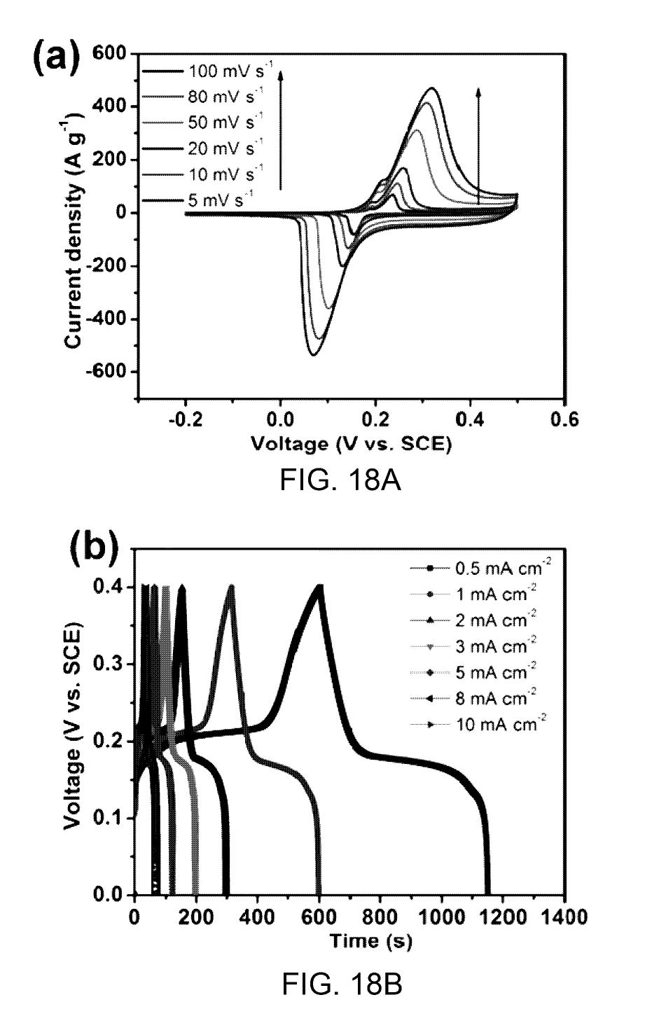

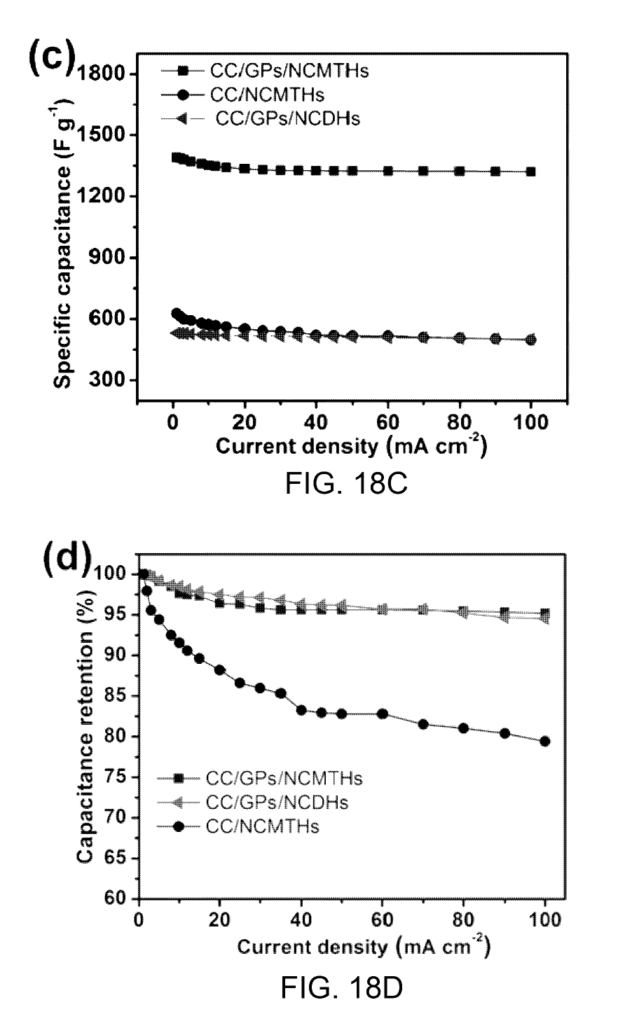

FIGS. 18A to 18D contain results of the characteristic electrochemical performance of the hybrid electrodes. FIG. 18A shows typical cyclic voltammetry (CV) profiles at scan rates from 5 to 100 mV s⁻¹ with a potential window from 0.2 to 0.5 V vs. SCE for CC/GPs/NCMTH electrodes in 2 M KOH aqueous electrolyte. Two clear redox peaks appeared in the CV curves corresponding to the redox reactions between NCMTHs and the alkaline electrolyte. FIG. 18B provides galvanostatic charge/discharge profiles at different current densities ranging from 0.5 to 10 mA cm⁻². At a low current density of 1 mA cm⁻², the CC/GPs/NCMTHs exhibited a specific capacitance of 1400 F g⁻¹ approximately 2.3 and 2.7 times higher than those of CC/NCMTH and CC/GPs/NCDHs, respectively, and comparable to or typically higher than the reported values of conventional metal hydroxide-based pseudocapacitor electrodes. The enhanced specific capacitance of the CC/GPs/NCMTH as compared to CC/GPs/NCDH electrodes corroborated the synergistic effects of Ni, Co and Mn in the metal hydroxides. The enhanced performance of CC/GPs/NCMTHs can also be attributed to the synergistic effect of GPs and the multi-component metal hydroxide. As indicated in FIGS. 18C and 18D, specific capacitances of all three different electrodes showed a gradual attenuation as the discharge current density increases. FIG. 18D plots the comparative rate capabilities of CC/GPs/NCMTH, CC/NCMTH and CC/GPs/NCDH electrodes, evaluated by calculating the capacitance retention as a function of discharge current densities from 1 to 100 mA cm⁻². FIG. 18D exhibits that the capacitance retention of CC/GPs/NCMTH electrodes reached as high as 95.6% at a high current density of 100 mA cm⁻² (equivalent to approximately 167 A g⁻¹) compared to that at 1 mA cm⁻², significantly higher than that of CC/NCMTH electrodes (79%) and slightly higher than that of CC/GPs/NCDH electrodes (94.8%). These results are substantially better than the reported rate capabilities of the state-of-the-art single- and double-component metal hydroxides, which fall in the range of 40 to 80%. The observed high rate capability can be primarily attributed to the large amounts of protruding GP sharp edges, the GP/NCMTH (edge-tip) structures, large surface area, binder-free fabrication process, high conductivity of GP substrates coated with NCMTHs, and contiguous fiber-petal transition with crystalline continuity, since high rate capability is mainly determined by the kinetics of ion diffusion and electrical conductivity of the electrode materials.

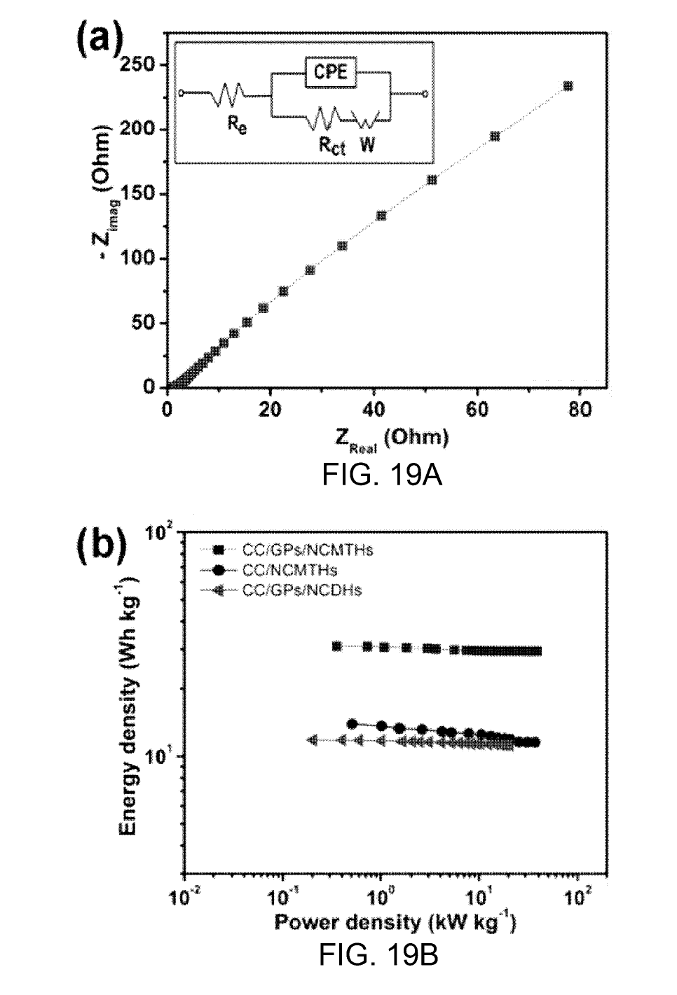

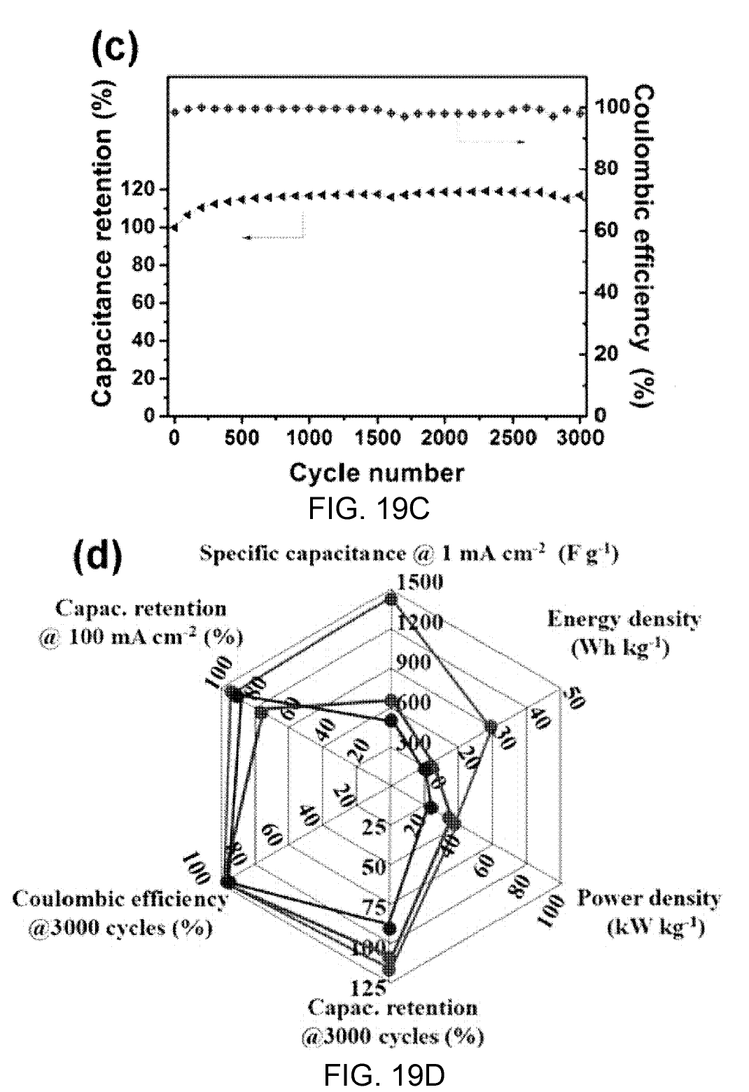

FIG. 19A shows a Nyquist plot for the CC/GPs/NCMTH electrodes recorded from 0.1 Hz to 1 MHZ. The Re value calculated from FIG. 19A for the CC/GPs/NCMTH electrodes is as low as 1.3Ω. As shown in a comparative Ragone plot (see FIG. 19B) for the CC/GPs/NCMTH, CC/NCMTH and CC/GPs/NCDH electrodes at different current densities, the CC/GPs/NCMTH electrode delivers an energy density of 0.30 Wh kg⁻¹ at a power density of 0.39 kW kg⁻¹. On the other hand, CC/NCMTH and CC/GPs/NCDH electrodes exhibited energy densities of about 11.5 Wh kg⁻¹ at a power density of 37 kW kg⁻¹ and about 11.2 Wh kg⁻¹ at a power density of 21 kW kg⁻¹, respectively. The energy and power densities of CC/GPs/NCMTH electrodes were comparable or superior to those reported for different metal hydroxide electrodes at high current densities. The cyclic stability of the three-dimensional CC/GPs/NCMTH hybrid composite electrodes was evaluated at a current density of 10 mA cm⁻² in the potential range of 0 to 0.4 V over 3000 cycles, as shown in FIG. 19C, in which specific capacitance retention is plotted as a function of cycle number. The three-dimensional CC/GPs/NCMTH hybrid electrode exhibited 117% capacitance retention over 3000 charge/discharge cycles and high coulombic efficiencies (>99%), indicating excellent long-term cyclic stability and high charge storage efficiencies. The radar plot in FIG. 19D summarizes the overall electrochemical performance of the three-dimensional CC/GPs/NCMTH hybrid electrodes and compared to those of CC/GPs/NCDH and CC/NCMTH electrodes efficiently. Generally, a larger area encompassed within a radar plot indicates better overall electrochemical performance. FIG. 19D indicates that the enclosed area within the red lines corresponding to CC/GPs/NCMTH hybrid electrodes is larger than those corresponding to CC/GPs/NCDH (blue color) and CC/NCMTH (green color) electrodes, respectively, corresponding to better overall electrochemical performance.

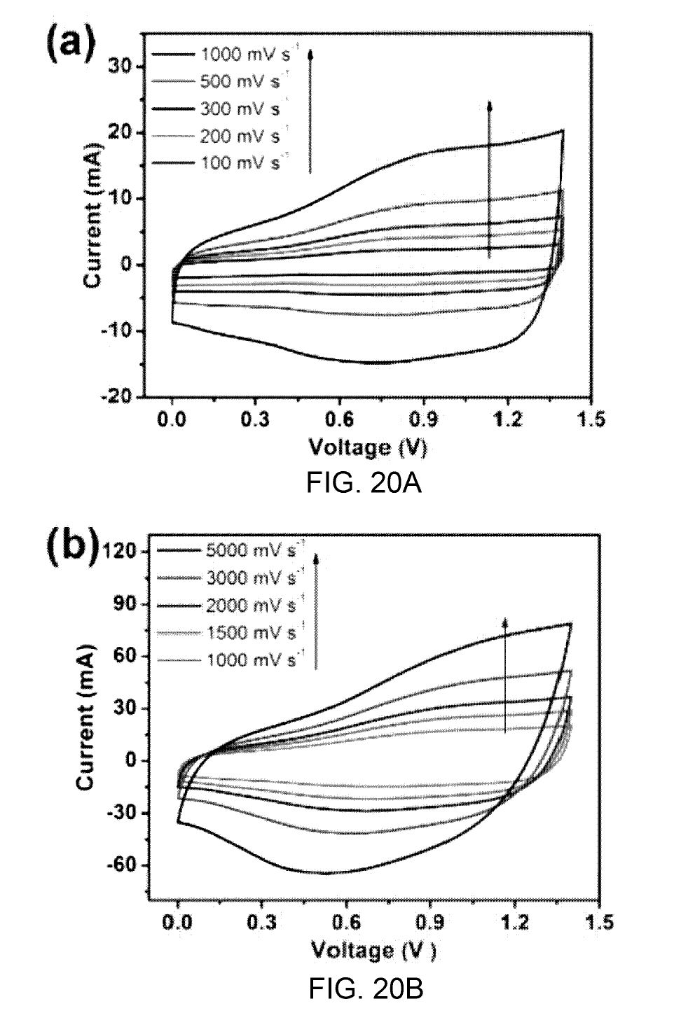

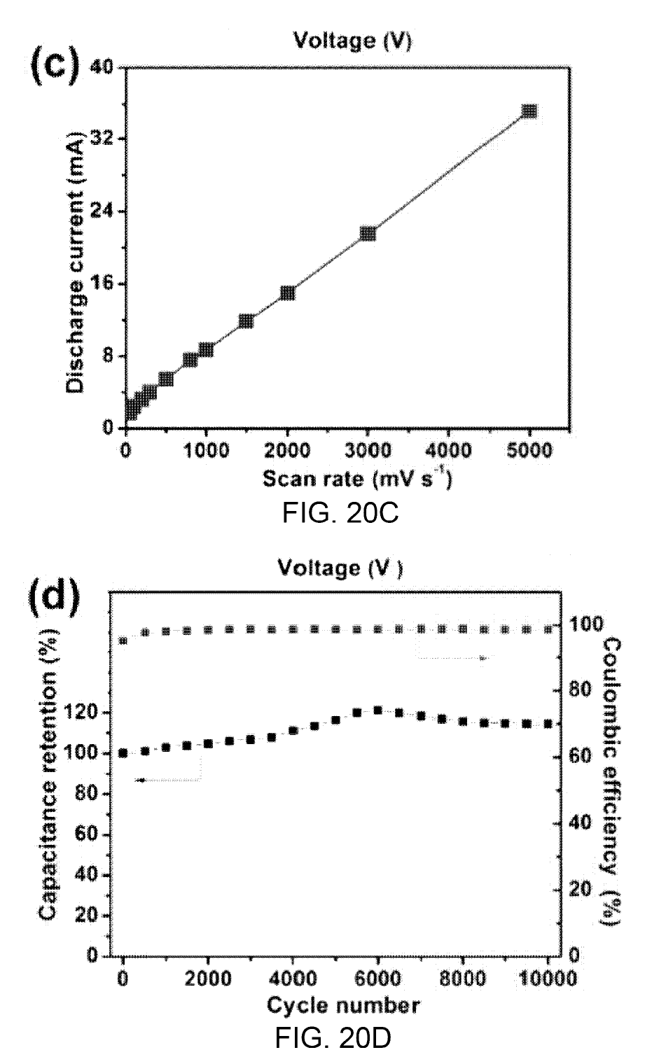

As indicated in FIG. 20D, the device capacitance gradually increased with cycle number until the 6000^{th} cycle (approx.), and then decreased steadily through the end of testing (10,000^{th} cycle), with a capacitance retention of 114% compared to the first cycle, which is significantly better than state-of-the-art hydroxide-based asymmetric devices reported in prior work.

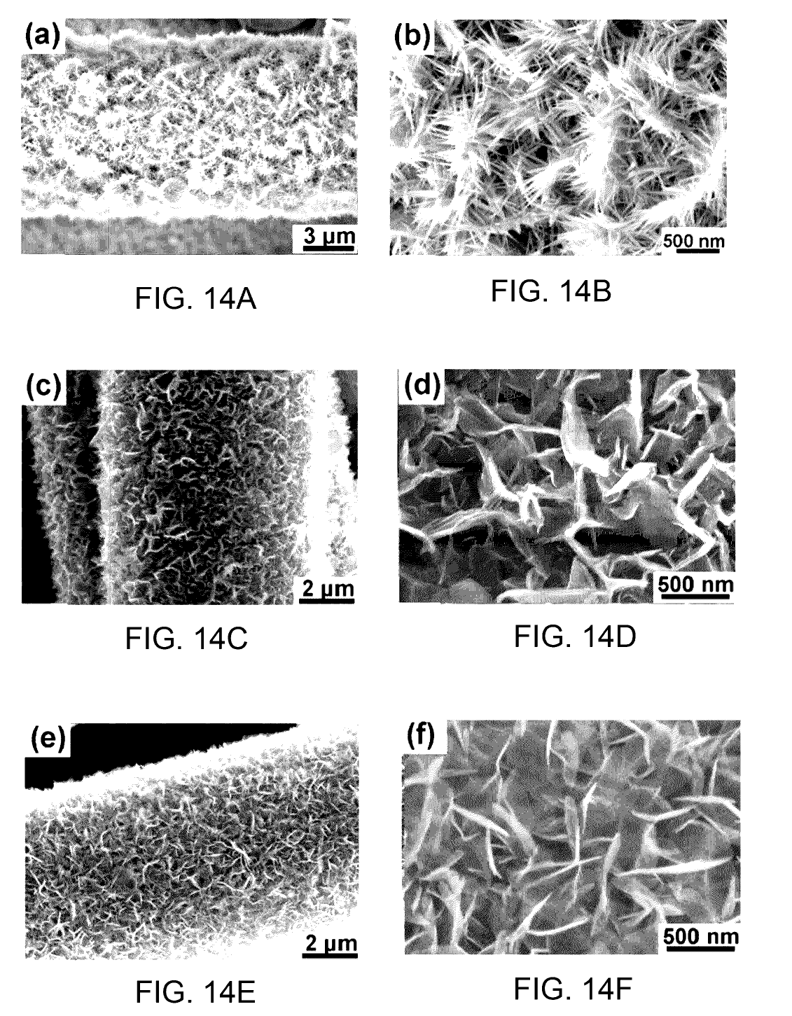

In view of the above results summarized in FIGS. 10 through 20D, a nanoarchitecture based on a three-dimensional CC/GPs/NCMTH hybrid is believed to be suitable for supercapacitor electrode applications. These hybrid pseudocapacitive electrodes exhibited high rate capability, high energy and power density, and excellent long-term cycle life in a three-electrode configuration cell, and showed tremendous potential as high-rate and long-cycle-life positive electrodes for two-terminal asymmetric supercapacitor devices. The electrochemical performance of the pseudocapacitive electrodes can be improved by adjusting factors such as the ratio of the multi-component metal elements in the NCMTHs and GP growth time. These results suggest that the combination of well-anchored nanopetals on the versatile carbon cloth substrate with a pseudocapacitive material is particularly well-suited for practical implementation as a high-rate, durable pseudocapacitive electrode.

In view of the forgoing investigations, it was concluded that pseudocapacitive electrodes in accordance with certain aspects of the invention are capable of providing improved electrochemical performance over conventional electrodes. In particular, tri-metal hydroxides and oxide materials appear to have potential for significantly increased performance over state-of-the-art single- and double-component metal hydroxides and oxides. Furthermore, the specific structural combinations disclosed herein including, but not limited to, an array of nanoneedles or nanopetals formed on a foam substrate, a free-standing graphene nanopetal foam substrate, or a graphitic nanopetal/carbon cloth substrate exhibited overall performance improvements and were therefore concluded to be particularly well-suited for implementation as pseudocapacitive electrodes as well as other electrochemical systems such as lithium ion batteries, fuel cells and non-enzymatic biosensors.

While the invention has been described in terms of specific embodiments, it is apparent that other forms could be adopted by one skilled in the art. For example, the physical configuration of the pseudocapacitive material could differ from that shown and described, and materials and processes other than those noted could be used. Therefore, the scope of the invention is to be limited only by the following claims.

1. A pseudocapacitive electrode comprising a tri-metal oxide or a tri-metal hydroxide.

2. A pseudocapacitive electrode comprising:
a porous substrate;
a nanoscale structure comprising an array of nanoneedles or an array of nanopetals located on the substrate, the nanoscale structure comprises a bi- or tri-metal oxide or a bi- or tri-metal hydroxide.

3. The pseudocapacitive electrode of claim 2, wherein the nanoscale structure comprises an array of nanoneedles and the substrate comprises a foam material.

4. The pseudocapacitive electrode of claim 2, wherein the nanoscale structure comprises an array of nanopetals and the substrate comprises a free-standing graphene nanopetal foam.

5. The pseudocapacitive electrode of claim 2, wherein the nanoscale structure comprises an array of nanoneedles and the substrate comprises a carbon cloth.

6. The pseudocapacitive electrode of claim 2, wherein the nanoscale structure comprises an array of nanoneedles and the substrate comprises an array of graphitic nanopetals located on a carbon cloth.

7. The pseudocapacitive electrode of claim 2, wherein the nanoscale structure comprises a bi-metal oxide or a bi-metal hydroxide.

8. The pseudocapacitive electrode of claim 2, wherein the nanoscale structure comprises a tri-metal oxide or a tri-metal hydroxide.

9. A method of forming a pseudocapacitive electrode, the method comprising:
providing a porous substrate; and then
forming a nanoscale structure comprising an array of nanoneedles or an array of nanopetals on the substrate, the nanoscale structure comprising a bi- or tri-metal oxide or a bi- or tri-metal hydroxide.

10. The method of claim 9, wherein the step of forming the nanoscale structure on the substrate comprises forming an array of nanoneedles on a surface of the substrate.

11. The method of claim 10, wherein the array of nanoneedles is formed using a hydrothermal deposition process.

12. The method of claim 9, wherein the step of forming the nanoscale structure on the substrate comprises forming an array of nanopetals on a surface of the substrate.

13. The method of claim 12, wherein the array of nanopetals is formed using a electrodeposition process.

14. The method of claim 9, wherein the substrate is a foam material and the step of forming the nanoscale structure on the substrate comprises forming an array of nanoneedles on a surface of the substrate using a hydrothermal process.

15. The method of claim 9, wherein the substrate comprises a free-standing graphene nanopetal foam and the step of forming the nanoscale structure on the substrate comprises growing an array of nanopetals on a surface of the substrate using an electrodeposition process.

16. The method of claim 9, wherein the substrate comprises graphite nanopetals formed on a carbon cloth material and the step of forming the nanoscale structure on the substrate comprises growing an array of nanoneedles on a surface of the substrate using a hydrothermal process.

17. The method of claim 9, wherein the step of providing the porous substrate comprises:
growing an array of graphitic nanopetals on a foam template via microwave plasma chemical vapor deposition; and then
chemically dissolving the foam template to produce a free-standing graphene nanopetal foam.

18. The method of claim 17, wherein the step of forming the nanoscale structure on the substrate comprises forming an array of nanopetals on the graphitic nanopetals of the free-standing graphene nanopetal foam using an electrodeposition process.

19. The method of claim 9, wherein the step of providing the porous substrate comprises forming an array of graphitic nanopetals on a carbon cloth material.

20. The method of claim 19, wherein the step of forming the nanoscale structure on the substrate comprises forming an array of nanoneedles on the graphitic nanopetals using a hydrothermal process.
